(19) United States
(12) Patent Application Publication
(10) Pub. No.: US 2026/0018435 A1
(43) Pub. Date: Jan. 15, 2026

(54) LED SUBSTRATE HEATER FOR DEPOSITION APPLICATIONS

(71) Applicant: LAM RESEARCH CORPORATION, Fremont, CA (US)

(72) Inventors: Vijay Kumar BADAM, Bangalore (IN); Karl Frederick LEESER, West Linn, OR (US)

(21) Appl. No.: 18/992,079

(22) PCT Filed: Jun. 21, 2023
(86) PCT No.: PCT/US2023/025816

§ 371 Date: Jan. 7, 2025

Related U.S. Application Data
(60) Provisional application No. 63/388,721, filed on Jul. 13, 2022.

(51) Int. Cl. H01L 21/67; H10H 29/03

(52) U.S. Cl. CPC H01L 21/67115; H01L 21/67144; H10H 29/03

(57) ABSTRACT

A pedestal configured to deposit material on a substrate includes a stem portion of the pedestal and a base portion of the pedestal mounted to the stem portion of the pedestal. The base portion includes an array of optical elements configured to emit light to optically heat the substrate.

### CROSS-REFERENCE TO RELATED APPLICATIONS

This application claims the benefit of U.S. Provisional Application No. 63/388,721, filed on Jul. 13, 2022. The entire disclosure of the above application is incorporated herein by reference.

### FIELD

The present disclosure relates generally to semiconductor processing system and more particularly to a LED substrate heater for deposition applications.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of processing chambers (also called process modules) to perform deposition, etching, and other treatments of substrates such as semiconductor wafers. Examples of processes that may be performed on a substrate comprise chemical vapor deposition (CVD), plasma enhanced CVD (PECVD), chemically enhanced plasma vapor deposition (CEPVD), atomic layer deposition (ALD), and plasma enhanced ALD (PEALD). Additional examples of processes that may be performed on a substrate comprise etching (e.g., chemical etching, plasma etching, reactive ion etching, etc.).

During processing, a substrate is arranged on a substrate support or a susceptor such as a pedestal, an electrostatic chuck (ESC), and so on in a processing chamber of the substrate processing system. In some processes, during deposition, gas mixtures comprising one or more precursors are introduced into the processing chamber, and plasma may be struck to activate chemical reactions. In other processes, during etching, gas mixtures comprising etch gases are introduced into the processing chamber, and plasma may be struck to activate chemical reactions. A computer-controlled robot is used to transfer substrates from one processing chamber to another in a sequence in which the substrates are to be processed.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is typically performed in a heated processing chamber. The processing chamber is maintained at a sub-atmospheric pressure using a vacuum pump and a controlled flow of an inert gas. The substrate to be coated with a film is placed in the processing chamber and is allowed to equilibrate with the temperature of the processing chamber before starting the ALD process.

### SUMMARY

A pedestal configured to deposit material on a substrate comprises a stem portion of the pedestal and a base portion of the pedestal mounted to the stem portion of the pedestal. The base portion comprises an array of optical elements configured to emit light to optically heat the substrate.

In additional features, the optical elements comprise light emitting diodes.

In additional features, the optical elements comprise light emitting diodes configured to emit light having wavelengths between 530 nm and 1000 nm.

In additional features, the base portion and the array are coplanar.

In additional features, the base portion and the array are circular and the optical elements are arranged in concentric circles from an inner diameter to an outer diameter of the array.

In additional features, the base portion and the array are circular and an outer diameter of the array is less or equal to an outer diameter of the base portion.

In additional features, the base portion and the array are circular and an outer diameter of the array is less or equal to an outer diameter of the substrate.

In additional features, the base portion and the array are circular and an outer diameter of the array is at least equal to an outer diameter of the substrate.

In additional features, the array is embedded in a cavity formed in an upper region of the base portion and the array further comprises an optically transparent window covering the optical elements.

In additional features, the array further comprises an optically transparent window having a first side covering the optical elements and a second side facing the substrate.

In additional features, the optical elements are arranged on a printed circuit board (PCB). The array further comprises an optically transparent window sealingly attached to the PCB. A reflective material is disposed on inside portions of the optical array to reflect the light from the optical elements to the substrate.

In additional features, the array further comprises one or more driver circuits configured to control power supply to the optical elements.

In additional features, the array further comprises one or more driver circuits configured to control operation of selected ones of the optical elements.

In additional features, the array comprises a printed circuit board on which the optical elements are arranged and one or more driver circuits to drive the optical elements. The one or more driver circuits and the optical elements are arranged on the same side of the printed circuit board.

In additional features, the array comprises a printed circuit board on which the optical elements are arranged and one or more driver circuits to drive the optical elements. The one or more driver circuits and the optical elements are arranged on opposite sides of the printed circuit board.

In additional features, the array comprises a printed circuit board and a plurality of driver circuits to drive the optical elements. The optical elements and at least one of the driver circuits is arranged on the same side of the printed circuit board. At least one of the driver circuits is arranged on an opposite side of the printed circuit board than the side on which the optical elements are arranged.

In additional features, the pedestal further comprises a shaft disposed through centers of the stem portion, the base portion, and the array; and an actuator coupled to the shaft and configured to move the substrate relative to the pedestal.

In additional features, the pedestal further comprises a shaft disposed through centers of the stem portion, the base portion, and the array; and an actuator coupled to the shaft and configured to move the substrate perpendicularly relative to a plane in which the base portion lies.

In additional features, the pedestal further comprises a shaft disposed through centers of the stem portion, the base portion, and the array; and an actuator coupled to the shaft and configured to rotate the substrate relative to the base portion.

In additional features, the array further comprises an optically transparent window covering the optical elements. The pedestal further comprises a shaft and an actuator. The shaft is disposed through centers of the stem portion, the base portion, and the array. The shaft comprises a conduit to receive a gas and a plurality of holes in fluid communication with the conduit near a first end of the shaft proximate to the array. The actuator is coupled to a second end of the shaft and configured move the substrate perpendicularly relative to a plane in which the base portion lies. The plurality of holes supply the gas radially over the window when the shaft is raised above the array.

In additional features, the array further comprises an optically transparent window having a first side covering the optical elements and a second side facing the substrate. The window comprises a plurality of mesas on the second side.

In additional features, the array further comprises an optically transparent window having a first side covering the optical elements and a second side facing the substrate. The window comprises a plurality of mesas arranged on the second side interstitially with an arrangement of the optical elements in the array.

In additional features, the base portion and the array are circular. The optical elements are arranged in concentric circles from an inner diameter to an outer diameter of the array. The array further comprises a circular and optically transparent window having a first side covering the optical elements and a second side facing the substrate. The window comprises a plurality of mesas arranged in concentric circles on the second side interstitially relative to the optical elements.

In additional features, the pedestal further comprises a shaft and an actuator. The shaft is disposed through centers of the stem portion, the base portion, and the array. The shaft comprises a conduit to receive a gas and a plurality of holes in fluid communication with the conduit near a first end of the shaft proximate to the array. The actuator is coupled to a second end of the shaft and configured move the substrate perpendicularly relative to a plane in which the base portion lies. The plurality of holes supply the gas radially over the window and the mesas when the shaft is raised above the array.

In additional features, the pedestal further comprises a plurality of conduits disposed in the stem and base portions to receive a gas and a plurality of holes at a periphery of the base portion, the holes being level with the mesas on the window and in fluid communication with the conduits. The holes supply the gas radially over the window and the mesas.

In additional features, the array further comprises an optically transparent window covering the optical elements and a plurality of electrodes disposed in the window to electrostatically clamp the substrate to the pedestal.

In additional features, the window and the electrodes are coplanar.

In additional features, the electrodes comprise an optically transparent and electrically conductive material.

In additional features, the electrodes comprise a metallic material. The electrodes comprise holes aligned with the optical elements.

In additional features, pedestal further comprises a layer of an optically transparent and electrically conductive material disposed between the electrodes and the optical elements.

In additional features, the window, the electrodes, the layer, and the optical elements lie in respective parallel planes that are parallel to the base portion of the pedestal.

In additional features, the pedestal further comprises a layer of an optically transparent and electrically conductive material disposed in the window with one side of the layer facing the electrodes and an opposite side of the layer facing the optical elements.

In additional features, the window, the electrodes, the layer, and the optical elements lie in respective parallel planes that are parallel to the base portion of the pedestal.

In additional features, the pedestal further comprises a plurality of conduits routed through the stem and base portions and the array and a vacuum pump configured to clamp the substrate to the pedestal using vacuum clamping.

In additional features, the pedestal further comprises a plurality of clamping pins arranged on a periphery of the base portion and an actuator coupled to the clamping pins and configured to clamp the substrate.

In additional features, the pedestal further comprises a ring disposed in the base portion adjacent to the array and coupled to the actuator and a plurality of shafts disposed in the base portion. The shafts are coupled to the ring and attached to respective ones of the clamping pins.

In additional features, the shafts are arranged around the array.

In additional features, the shafts pass through pins the array.

In additional features, the actuator is configured to actuate the ring in a first direction to clamp the substrate and in a second direction to de-clamp the substrate.

In additional features, the array further comprises an optically transparent window covering the optical elements and extending to a periphery of the base portion. The pedestal further comprises a plurality of clamping pins arranged on the window near the periphery of the base portion and an actuator coupled to the clamping pins and configured to clamp the substrate.

In additional features, a method of depositing material on a substrate in a processing chamber, the method comprises loading the substrate into the processing chamber and optically heating the substrate using an array of optical elements embedded in a base portion of a pedestal in the processing chamber.

In additional features, the method further comprises holding the substrate above the pedestal and preheating the substrate by supplying power to the optical elements at a first power level.

In additional features, the method further comprises, after the preheating, lowering the substrate onto the pedestal and heating the substrate by supplying power to the optical elements at a second power level that is different than the first power level.

In additional features, the method further comprises, after the preheating, heating the substrate by supplying power to the optical elements at a second power level that is different than the first power level, and lowering the substrate onto the pedestal.

In additional features, the method further comprises clamping the substrate to the pedestal using electrostatic clamping, vacuum clamping, or mechanical clamping.

In additional features, the method further comprises establishing other conditions for processing the substrate. The other conditions comprise supplying gas and vapor flows through a showerhead, adjusting substrate-to-showerhead gap, and exciting plasma in the processing chamber.

In additional features, the method further comprises depositing the material on the substrate using plasma enhanced chemical vapor deposition or atomic layer deposition.

In additional features, the method further comprises reducing power supplied to the array to a third power level.

In additional features, the method further comprises lifting the substrate from the pedestal and removing the substrate from the processing chamber.

In additional features, the method further comprises establishing other conditions for processing the substrate. The other conditions comprise supplying gas and vapor flows through a showerhead, adjusting substrate-to-showerhead gap, and exciting plasma in the processing chamber. The method further comprises depositing the material on the substrate using plasma enhanced chemical vapor deposition or atomic layer deposition. The method further comprises reducing power supplied to the array to a third power level. The method further comprises lifting the substrate from the pedestal and removing the substrate from the processing chamber.

In additional features, the method further comprises clamping the substrate to the pedestal using electrostatic clamping, vacuum clamping, or mechanical clamping. The method further comprises establishing other conditions for processing the substrate. The other conditions comprising supplying gas and vapor flows through a showerhead, adjusting substrate-to-showerhead gap, and exciting plasma in the processing chamber. The method further comprises depositing the material on the substrate using plasma enhanced chemical vapor deposition or atomic layer deposition. The method further comprises reducing power supplied to the array to a third power level. The method further comprises lifting the substrate from the pedestal and removing the substrate from the processing chamber.

In additional features, the method further comprises arranging the substrate on the pedestal and heating the substrate by supplying power to the array. The method further comprises establishing other conditions for processing the substrate. The other conditions comprise supplying gas and vapor flows through a showerhead, adjusting substrate-to-showerhead gap, and exciting plasma in the processing chamber. The method further comprises depositing the material on the substrate using plasma enhanced chemical vapor deposition or atomic layer deposition. The method further comprises reducing power supplied to the array. The method further comprises lifting the substrate from the pedestal and removing the substrate from the processing chamber.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a system for processing substrates according to the present disclosure;

FIG. 2A shows a plan view of an optical array used as a heating system of a pedestal in the system of FIG. 1 to heat substrates according to the present disclosure;

FIG. 2B shows a cross-sectional view of the optical array of FIG. 2A;

FIG. 2C shows a block diagram of a system for controlling the optical array used in a pedestal in the system of FIG. 1 to heat substrates according to the present disclosure;

FIGS. 3A and 3B show an example of a pedestal using vacuum clamping and comprising the optical array of FIG. 2A that can be used in the system of FIG. 1 to heat substrates according to the present disclosure;

FIG. 4A shows a plan view of an optical array comprising mesas to support substrates when the optical array is used in a pedestal in the system of FIG. 1 to heat the substrates according to the present disclosure;

FIG. 4B shows a cross-sectional view of the optical array of FIG. 4A;

FIGS. 4C and 4D show an example of a pedestal comprising the optical array of FIG. 4A that can be used in the system of FIG. 1 to heat substrates according to the present disclosure;

FIGS. 4E and 4F show another example of a pedestal comprising the optical array of FIG. 4A that can be used in the system of FIG. 1 to heat substrates according to the present disclosure;

FIG. 5A shows a plan view of an optical array comprising optically transparent clamping electrodes used to clamp a substrate to a pedestal used in the system of FIG. 1 to heat the substrate according to the present disclosure;

FIG. 5B shows a cross-sectional view of the optical array of FIG. 5A;

FIG. 6A shows a plan view of an optical array comprising metallic clamping electrodes used to clamp a substrate to a pedestal used in the system of FIG. 1 to heat the substrate according to the present disclosure;

FIG. 6B shows a cross-sectional view of the optical array of FIG. 6A;

FIG. 6C shows a biasing system comprising DC and AC (i.e., RF) power supplies to bias the clamping electrodes shown in FIGS. 5A-6B;

FIGS. 7A and 7B show an example of a pedestal using electrostatic clamping and comprising the optical array of FIG. 5A or FIG. 6A that can be used in the system of FIG. 1 to heat substrates according to the present disclosure;

FIG. 8A shows a plan view of the optical array of FIG. 5A further comprising a Faraday shield according to the present disclosure;

FIG. 8B shows a cross-sectional view of the optical array of FIG. 8A;

FIG. 9A shows a plan view of the optical array of FIG. 6A further comprising a Faraday shield according to the present disclosure;

FIG. 9B shows a cross-sectional view of the optical array of FIG. 9A;

FIGS. 10A and 10B show an example of a pedestal using electrostatic clamping and comprising the optical array of FIG. 8A or FIG. 9A that can be used in the system of FIG. 1 to heat substrates according to the present disclosure;

FIGS. 11A-11C show an example of a pedestal using mechanical clamping and comprising the optical array of FIG. 2A that can be used in the system of FIG. 1 to heat substrates according to the present disclosure;

FIGS. 12A-12C show another example of a pedestal using mechanical clamping and comprising the optical array of FIG. 2A that can be used in the system of FIG. 1 to heat substrates according to the present disclosure; and

FIG. 13 show a method a method of processing a substrate using any of the optical arrays and pedestals of FIGS. 2A-12C in the system of FIG. 1 according to the present disclosure.

In the drawings, reference numbers may be reused to identify similar and/or identical elements.

### DETAILED DESCRIPTION

Typically, resistively heated pedestals or susceptors are used for heating substrates in deposition applications. A pedestal comprises a thermally conductive body, usually fabricated from a metal such as aluminum, that monolithically houses a heater element that heats the thermally conductive body. The thermally conductive body spreads out heat flux to heat a substrate arranged on the pedestal during processing. Gas conduction combined with radiation between the substrate and the heated pedestal thermally couples the substrate to the pedestal.

Resistively heated pedestals have limited ability to tune or adjust localized heating of the substrate in a recipe-controllable manner because heating elements for localized heating are difficult to implement in the monolithic body of the pedestal. The ability to tune or adjust localized heating of the substrate is further limited because the thermally conductive body spreads out heat locally to enhance global temperature uniformity across the pedestal. In contrast, less thermally conductive materials such as ceramic struggle to balance sufficiently low thermal resistance to enable localized heating and sufficiently high fracture toughness and thermal shock resistance to prevent inadvertent fracture.

Instead, the present disclosure provides an optical array such as an LED array disposed in or on the pedestal for heating substrates. Unlike other heating elements, the optical array comprises optical elements such as LEDs that can emit light to optically heat a substrate. The optical array can tune or adjust localized heating of the substrate in a recipe-controllable manner. While substrates can be heated by light of shorter wavelengths, photo-induced corrosion can occur at wavelengths below 530 nm. Accordingly, wavelengths for optical heating of substrates are selected preferably between 530 nm and 1000 nm. The array-based heating provides recipe-controlled, highly tunable substrate heating to adjust thermal uniformity, improve unit process, and compensate for upstream or downstream process issues.

In vacuum deposition applications, the optical array is encapsulated in a sealed housing. The light from the optical array shines through an optically transparent window, generally made of quartz or sapphire, onto the substrate. In some examples, the substrate and the optical array may be stationary relative to each other. Alternatively, the substrate and the optical array may rotate relative to each other.

The window needs to be maintained clean to prevent optical transmission efficiency of the window from drifting due to parasitic deposition on the surface of the window. For applications where the substrate rests directly onto the window, purging schemes such as edge purging through an annulus or an annular arrangement of gas purge apertures can be used to maintain the window clean. Alternatively, if the substrate is separated off the window and process pressure is above a threshold (e.g., at least 40 Torr or so), a cross flow gas purging arrangement utilizing Coanda effect can be used. Alternatively, the window may be subjected to periodic dry and/or wet chemical cleaning. These features may also be utilized in aqueous (wet) deposition applications.

From an environmental, social, and governance (ESG) perspective, LEDs perform better than other heating elements. LED heating may be less efficient from electrical power to thermal power conversion perspective. However, due to the low temperature of the LEDs, LED heating can prevent radiative loss to the rest of the processing chamber. Additionally, the resistively heated pedestals or susceptors typically require significant heating time for establishing initial stable temperature and subsequently heating the substrate. In contrast, the LED heating does not require such a long heating time to heat substrate. Further, during maintenance cycle, the resistively heated pedestals typically require significant cool down time before maintenance can be performed. In contrast, the LED heater is cold and does not require such a long waiting period before maintenance can be performed. Further, the inside of the housing (e.g., base and sides) can be shaped and/or equipped with reflective material (e.g., reflective rings) to reflect and/or direct the light emitted by the LEDs onto the substrate. Due to directed heating provided by the LEDs, the optical array heats only the substrate and not the processing chamber. Further, LED heating can also provide zonal heating control for thermal-only, non-plasma applications. Therefore, LED heating provides a more efficient wafer heating system than other forms of heating.

As described below in detail, the present disclosure provides various configurations of pedestals comprising the LED array to heat substrates in deposition applications. For example, the LED array can heat the substrate in pedestal utilizing different types of clamping systems to clamp the substrate to the pedestal. Examples of clamping systems comprise vacuum clamping, electrostatic clamping, and mechanical clamping. For each clamping system, various systems for rotating the substrate relative to the LED array are described. Further, for each clamping and rotating system, various purging systems are described. These and other features of the present disclosure are described below in detail.

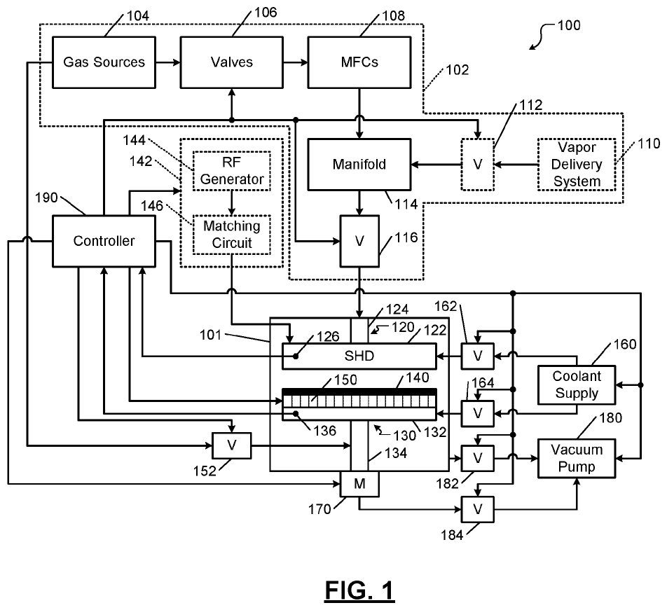

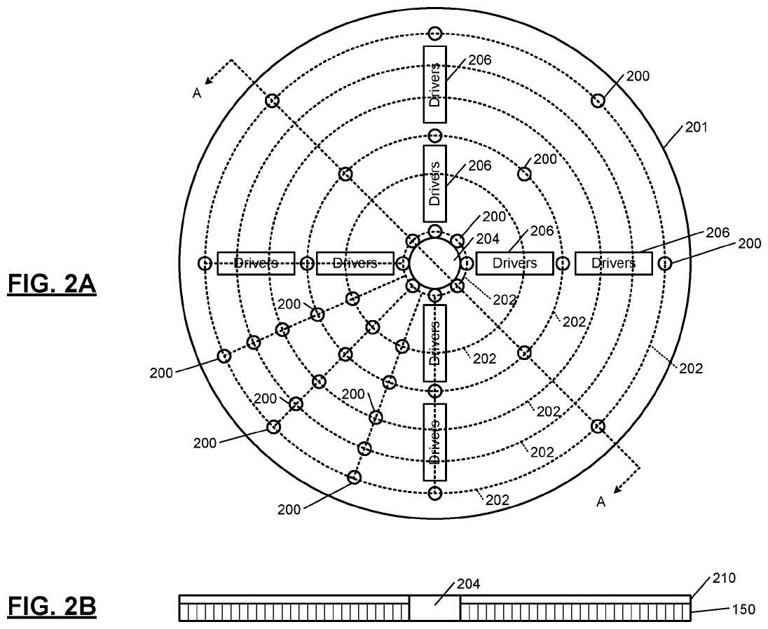

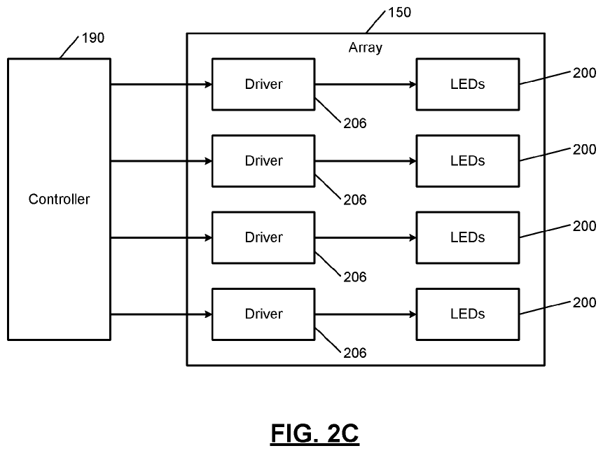

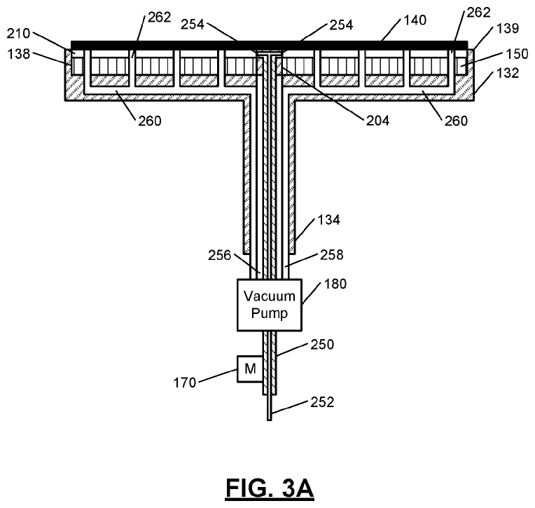

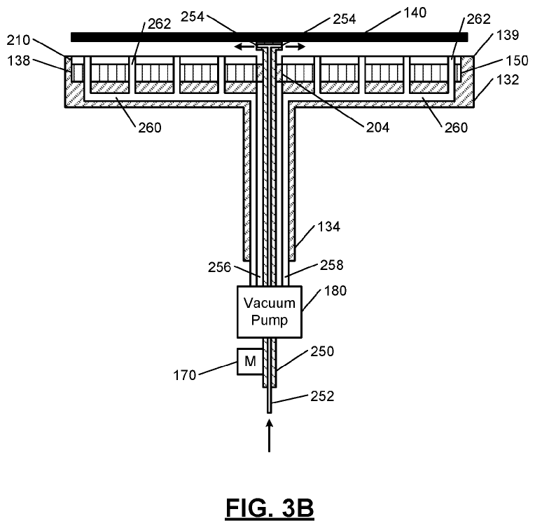

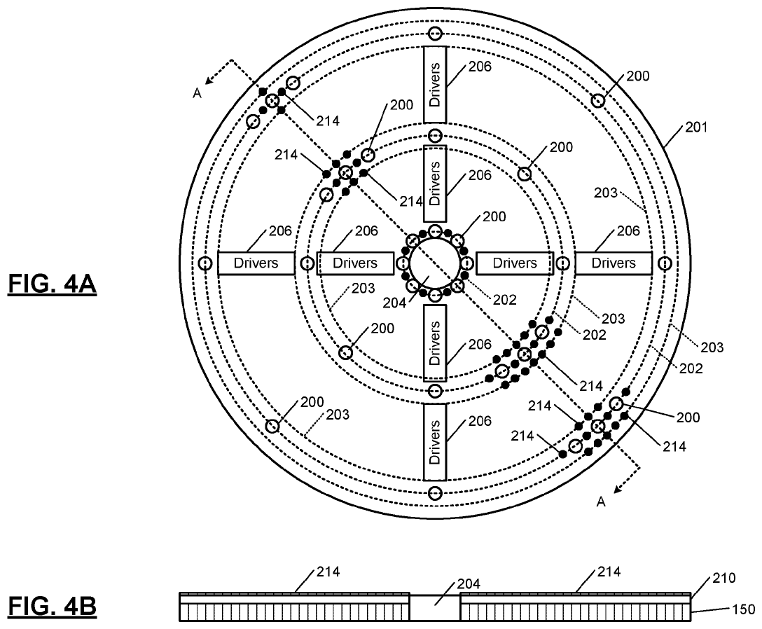

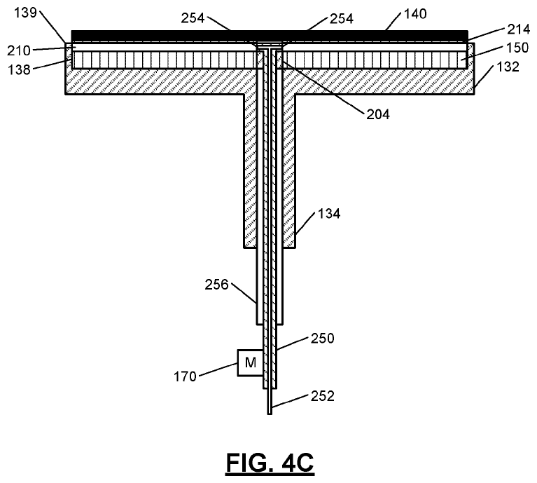

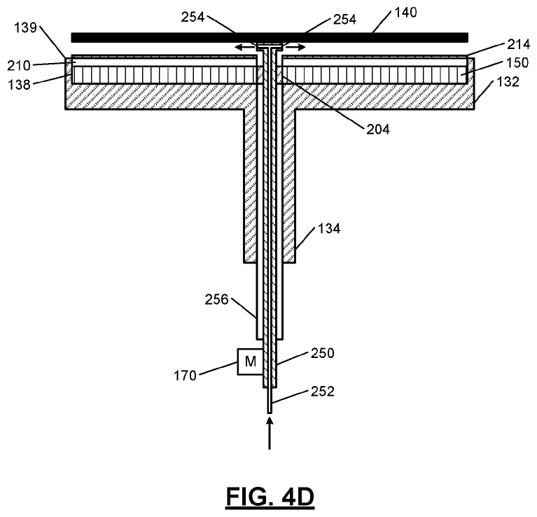

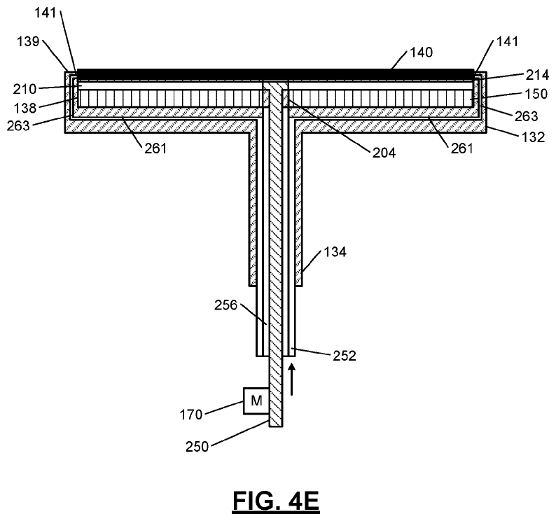

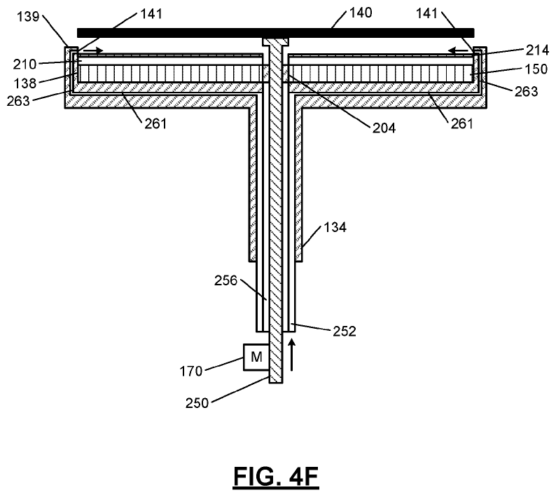

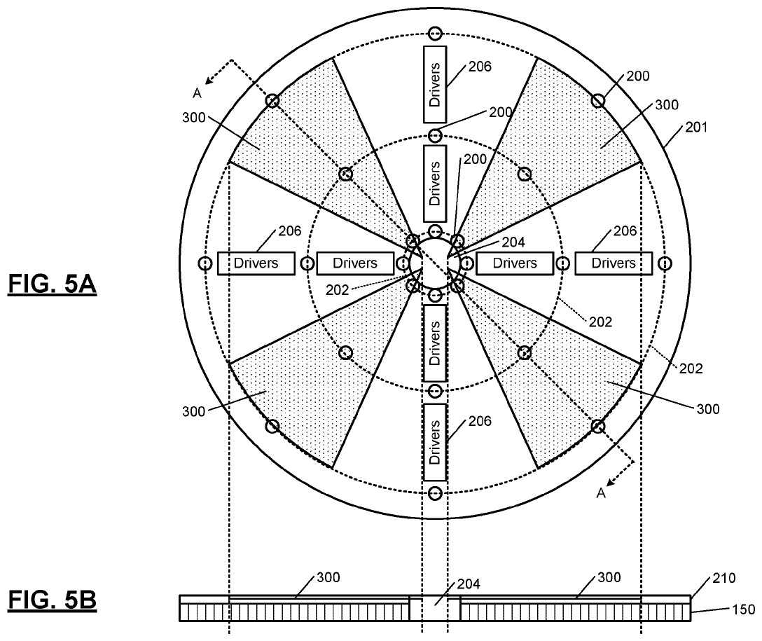

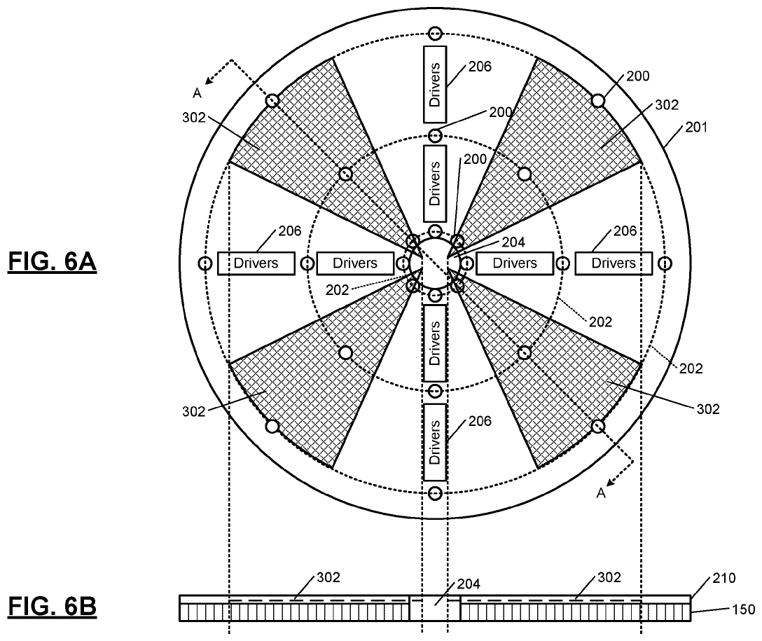

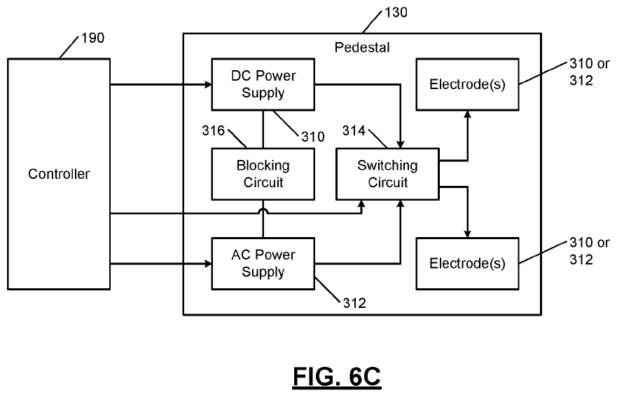

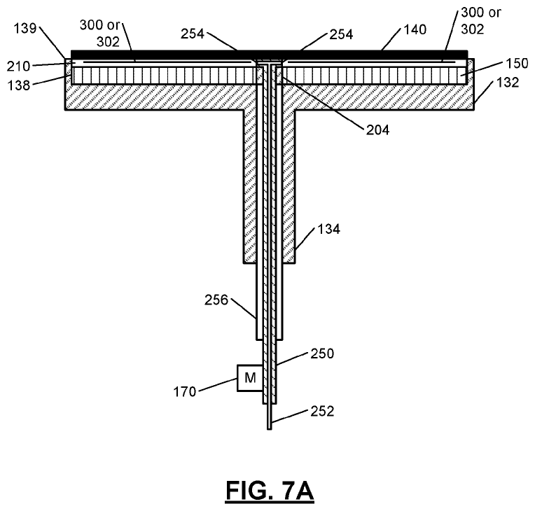

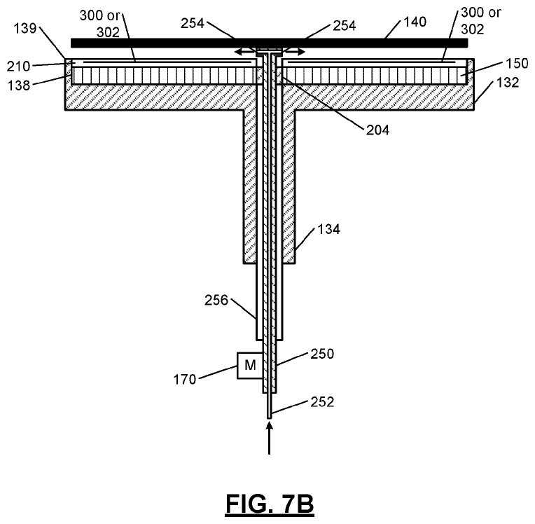

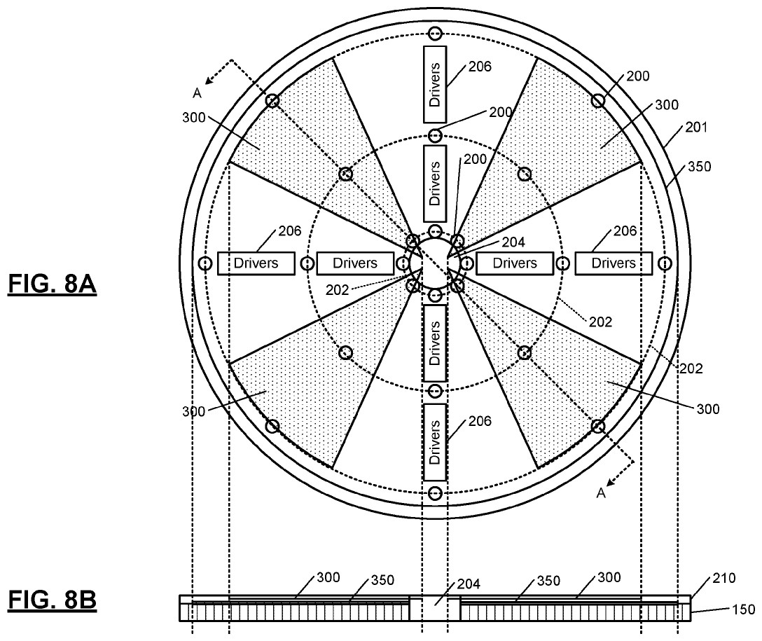

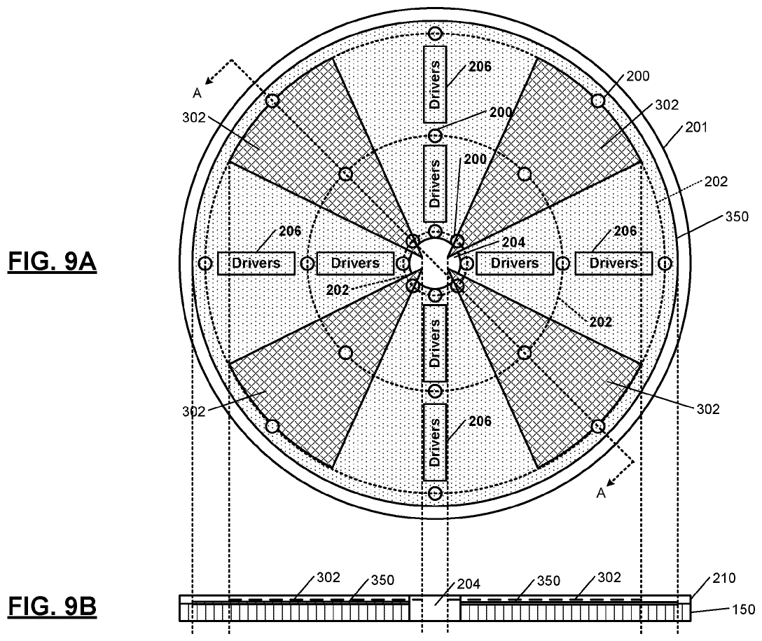

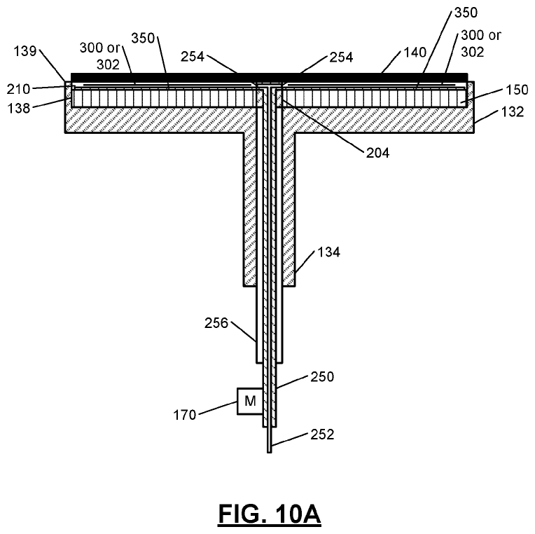

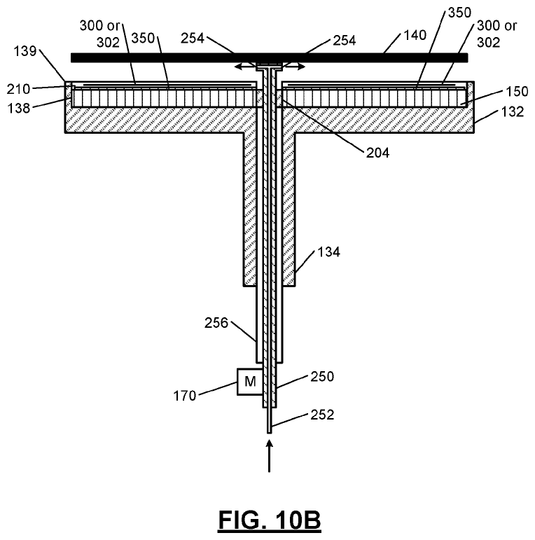

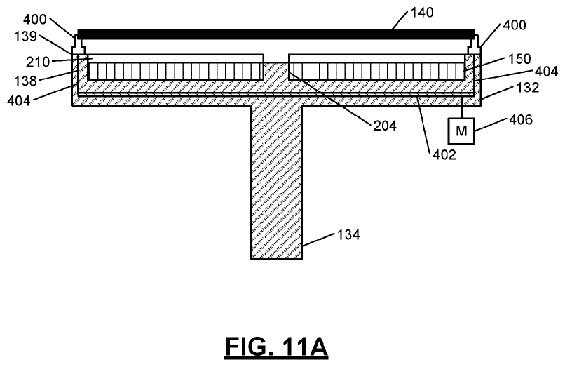

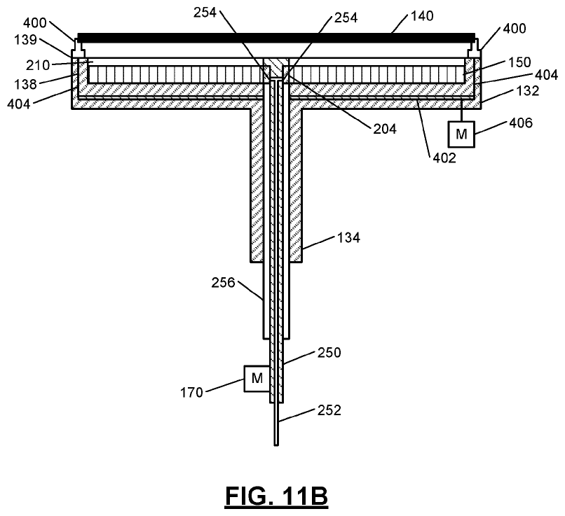

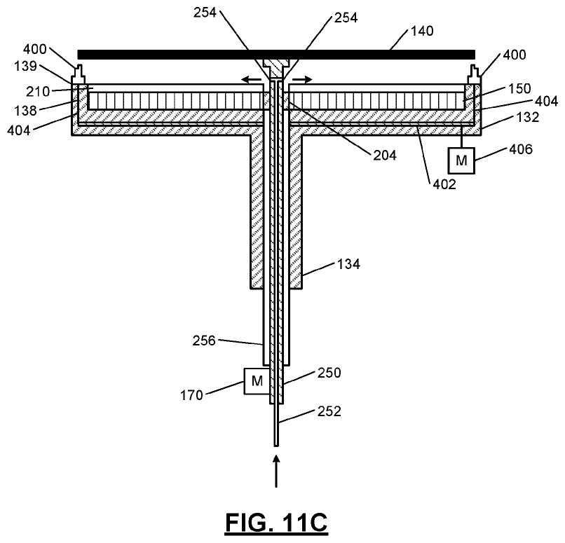

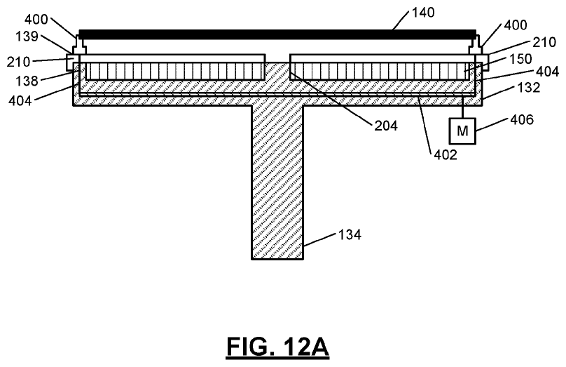

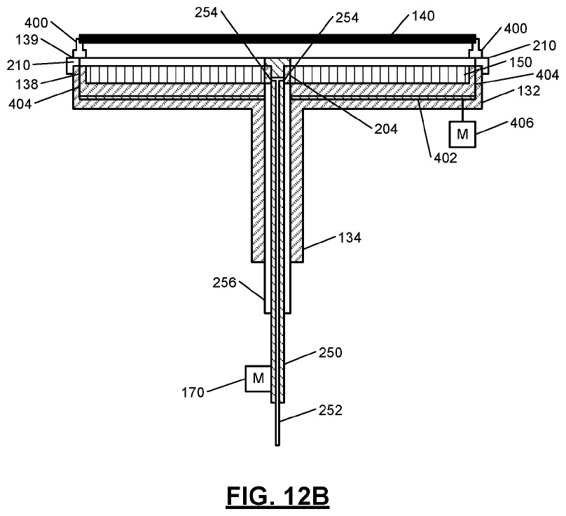

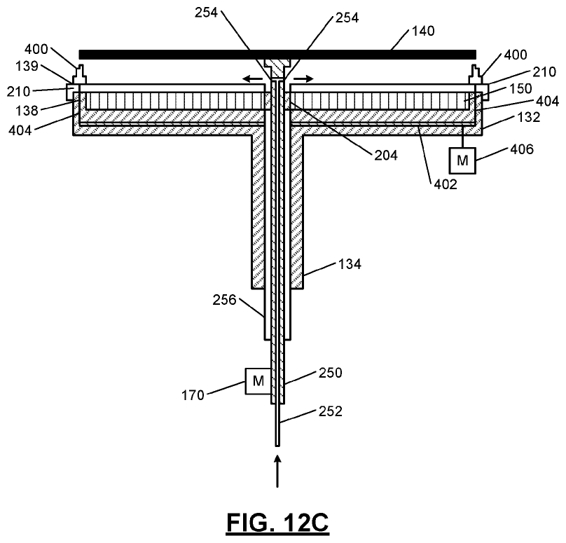

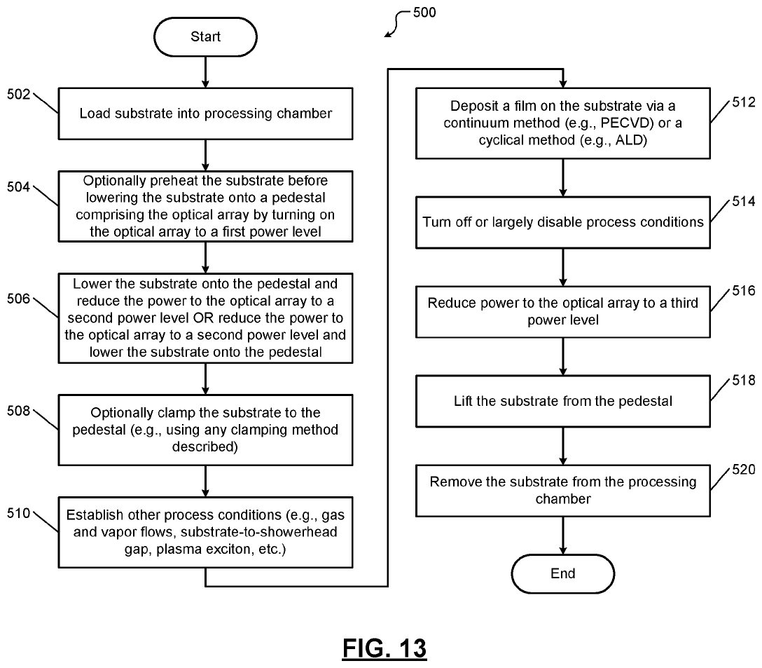

The present disclosure is organized in multiple sections as follows. In Section 1, an example of a system for processing substrates according to the present disclosure is shown and described with reference to FIG. 1. The system provides an example of an environment in which the various optical arrays and pedestal shown and described with reference to FIGS. 2A-13 can be implemented. In Section 2, an example of the optical array used in a pedestal in the system of FIG. 1 to heat substrates according to the present disclosure is shown and described with reference to FIGS. 2A-2C. In Section 3, an example of a pedestal using vacuum clamping and comprising the optical array used in the system of FIG. 1 to heat the substrates is shown and described with reference to FIGS. 3A and 3B. In Section 4, an example of an optical array comprising mesas to support substrates when the optical array is used in a pedestal in the system of FIG. 1 to heat the substrates is shown and described with reference to FIGS. 4A and 4B. Additionally, examples of pedestals comprising the optical array with the mesas that can be used in the system of FIG. 1 to heat substrates are shown and described with reference to FIGS. 4C-4F. In Section 5, examples of optical arrays comprising transparent and non-transparent clamping electrodes used for electrostatically clamping a substrate to a pedestal used in the system of FIG. 1 are shown and described with reference to FIGS. 5A-6C. Additionally, an example of a pedestal comprising the optical arrays comprising the clamping electrodes that can be used in the system of FIG. 1 is shown and described with reference to FIGS. 7A and 7B. In Section 6, examples of optical arrays comprising the clamping electrodes and further comprising a Faraday shield for use in a pedestal used in the system of FIG. 1 are shown and described with reference to FIGS. 8A-9B. Additionally, an example of a pedestal comprising the optical arrays comprising the clamping electrodes and the Faraday shield that can be used in the system of FIG. 1 is shown and described with reference to FIGS. 10A and 10B. In Section 7, examples of pedestals using mechanical clamping and comprising the optical array of FIG. 2A that can be used in the system of FIG. 1 to heat substrates are shown and described with reference to FIGS. 11A-12C. In Section 8, a method of processing a substrate using any of the optical arrays and pedestals of FIGS. 2A-12C in the system of FIG. 1 is shown and described with reference to FIG. 13.

### Section 1: Example of Substrate Processing System

FIG. 1 shows an example of a substrate processing system (hereinafter the system 100). The system 100 can be used to process substrates using chemical vapor deposition (CVD), plasma enhanced CVD (PECVD), chemically enhanced plasma vapor deposition (CEPVD), atomic layer deposition (ALD), or plasma enhanced ALD (PEALD) processes. An example of a method for processing a substrate using the system 100 is shown and described in detail with reference to FIG. 13.

The system 100 comprises a processing chamber 101 and a gas distribution system 102. The gas distribution system 102 comprises a plurality of gas sources 104, a plurality of valves 106 connected to the gas sources 104, a plurality of mass flow controllers (MFCs) 108 connected to the valves 106. The gas sources 104 supply various gases comprising process gases, precursors, purge gases, inert gases, cleaning gases, and so on. The MFCs 108 control the mass flow rates of the gases.

In some applications, the gas distribution system 102 further comprises a vapor delivery system 110 to supply one or more vaporized precursors through one or more valves 112. One or more gases from the MFCs 108 and, when used, one or more vaporized precursors are supplied to a mixing manifold 114. The gases or gas mixtures from the mixing manifold 114 are supplied to the processing chamber 101 through a valve assembly (e.g., a pulsed valve manifold or PVM assembly) 116.

The processing chamber 101 comprises a showerhead 120 and a pedestal 130. The showerhead 120 is attached to a top plate of the processing chamber 101. The showerhead 120 receives the gases or gas mixtures from the mixing manifold 114 through the valve assembly 116. The showerhead 120 comprises a base portion 122 and a stem portion 124. The stem portion 124 extends from the center of the base portion 122 and is attached to the top plate of the processing chamber 101. The base portion 122 is cylindrical and comprises a plurality of through holes (not shown) through which the gases or gas mixtures are supplied into the processing chamber 101.

The pedestal 130 comprises a base portion 132 and a stem portion 134. The stem portion 134 is generally cylindrical or can be Y-shaped, with the tapered (i.e., the top of the Y) portion attached to a bottom of the base portion 132. The stem portion 134 extends from the base portion 132 and is attached to the bottom of the processing chamber 101. The base portion 132 is also cylindrical. A substrate 140 is arranged on a top surface of the base portion 132 of the pedestal 130 during processing.

While not shown, the base portion 132 of the pedestal 130 may comprise lift pins to hold, lower, and raise the substrate 140 relative to the base portion 132 of the pedestal 130. Optionally, a shaft (shown and described below) extending through the stem portion 132 and the base portion 132 of the pedestal 130 may be used to hold, lower, and raise the substrate 140 relative to the base portion 132 of the pedestal 130. The lift pins and the shaft can be used in combination to hold, lower, and raise the substrate 140 relative to the base portion 132 of the pedestal 130.

The substrate 140 may be clamped to the base portion 132 using one of many clamping schemes. Examples of the clamping schemes comprise vacuum clamping, electrostatic clamping, and mechanical clamping. Various examples of the pedestal 130 comprising these clamping schemes are shown and described below. Any of the pedestals shown and described below can be used as the pedestal 130 in the processing chamber 101.

The base portion 132 comprises an optical array (e.g., an LED array) 150 to heat the substrate 140 as shown and described below in detail. The optical array 150 comprises optical elements (e.g., LEDs) and a transparent window (shown and described below). Through the window, light from the optical elements in the optical array 150 is incident on a bottom surface of the substrate 140 to heat the substrate 140. The substrate 140 may be heated while being held above the optical array 150 (e.g., by lift pins that pass through the optical array 150 or by the shaft). The substrate 140 may be heated when the substrate 140 rests on the optical array 150 without being clamped (e.g., on mesas shown and described below). The substrate 140 may be heated when the substrate 140 rests on the optical array 150 upon being clamped to the pedestal 130 using any of the clamping methods described below. An example of a method for processing the substrate 140 and heating the substrate 140 using the optical array 150 is shown and described in detail with reference to FIG. 13. The LEDs emit light having wavelengths selected preferably between 530 nm and 1000 nm for optical heating of the substrate 140.

A purge gas (e.g., an inert gas) from one of the gas sources 104 is supplied through a valve 152 to the stem portion 134. The purge gas flows radially over and across the window of the optical array 150 to clean the window and maintain the transparency of the window as explained below in detail. Various examples of the pedestal 130 comprising the optical array 150 and different purging schemes are shown and described below. Any of the pedestals shown and described below can be used as the pedestal 130 in the processing chamber 101.

In some applications (e.g., in PECVD and PEALD processes), plasma may be used to process the substrate 140. The system 100 comprises a radio frequency (RF) system 142 used to generate plasma in the processing chamber 101. The RF system 142 comprises a RF generator 144 and a matching circuit 146. The RF system 142 supplies RF power to the showerhead 120 while the pedestal 130 is grounded. Alternatively, while not shown, the RF power can be supplied to the pedestal 130 while the showerhead 120 is grounded. The RF power activates the gases or gas mixtures supplied through the showerhead 120 and generates plasma between the showerhead 120 and the substrate 140 arranged on the pedestal 130.

The showerhead 120 and the pedestal 130 comprise temperature sensors 126, 136 to sense the temperatures of the showerhead 120 and the pedestal 130. The showerhead 120 and the pedestal 130 comprise cooling channels (now shown). A coolant is circulated through the cooling channels to control the temperatures of the showerhead 120 and the pedestal 130. A coolant supply 160 may supply the coolant to the cooling channels in the showerhead 120 and the pedestal 130 via valves 162, 164.

One or more actuators generally shown at 170 may be used to move the pedestal 130 relative to the showerhead 120. One of the actuators 170 may also be used to move and rotate a shaft (shown and described below in detail) that passes through the stem portion 134 of the pedestal 130 to lift and rotate the substrate 140. The purge gas used to clean the window of the optical array 150 is supplied through the valve 152 via a conduit in the shaft as shown and described below in detail.

A vacuum pump 180 is connected to the bottom of the processing chamber 101 through a valve 182. The vacuum pump 180 is used to maintain vacuum in the processing chamber 101 and to evacuate reactants and process byproducts from the processing chamber 101. Additionally, when vacuum clamping is used, the vacuum pump 180 is connected to the stem portion 134 of the pedestal 130 through a valve 184. The vacuum pump 180 maintains vacuum through an annular volume around the shaft in the stem portion 134 of the pedestal 130 (shown and described below) to clamp the substrate 140 to the pedestal 130.

In addition, the stem portion 134 comprises a conduit (shown and described below) through which electrical connections are provided to various electrical elements disposed in the base portion 132 of the pedestal 130. For example, the electrical elements comprise the optical array 150, the temperature sensors 126, 136, and other electrical elements (e.g., clamping electrodes shown and described below) disposed in the base portion 132 of the pedestal 130.

A controller 190 controls the various elements of the system 100 (e.g., the gas distribution system 102, the valves, the RF system 142, the optical array 150, the coolant supply 160, the actuators 170, the vacuum pump 180, etc.). The controller 190 receives data from the temperature sensors 126, 136 and controls the temperatures of the showerhead 120 and the pedestal 130 by controlling the optical array 150 and the coolant supply 160. These and other features of the system 100 are described below in further detail.

### Section 2: Optical Array

FIGS. 2A-2C show an example of the optical array 150. FIG. 2A shows a top view of the optical array 150. FIG. 2B shows a cross-sectional view of the optical array 150 taken along line A-A shown in FIG. 2A. FIG. 2C shows a block diagram of the circuitry that controls the optical array 150.

In FIG. 2A, the optical array 150 is generally circular and has a radius that is less than an outer diameter (OD) of the base portion 132 of the pedestal 130. The radius of the optical array 150 is approximately equal or at least equal (i.e., similar) to a radius of the substrate 140. For example, the optical array 150 comprises a plurality of LEDs 200 arranged on a printed circuit board (PCB) 201. For example, the LEDs 200 are arranged on the PCB 201 in concentric circles 202. For example, a radius of the outermost concentric circle 202 comprising the LEDs 200 can be approximately equal to the radius of the substrate 140. Thus, the radius of the optical array 150 can be slightly greater than the radius of the substrate 140. While only a few concentric circles 202 are shown for illustrative purposes, the number of the concentric circles 202 may vary. For example, the concentric circles 202 may be denser than those shown. Further, the number of LEDs 200 in each concentric circle 202 may be more than that shown. Accordingly, the concentric circles 202 and the LEDs 200 are more densely arranged in the optical array 150 than shown. The concentric circles 202 and the LEDs 200 extend from an inner annular region 204 of the optical array 150 up to an OD of the optical array 150. The LEDs 200 emit light having wavelengths selected preferably between 530 nm and 1000 nm for optical heating of the substrate 140. The light emitted by the LEDs 200 optically heats the substrate 140.

The LEDs 200 may be arranged in the concentric circles 202 in different patterns. For example, the LEDs 200 in some of the concentric circles 202 may be arranged more densely than in other concentric circles 202. For example, the LEDs 200 in some portions (e.g., zones or quadrants) of the optical array 150 may be arranged more densely than in other portions of the optical array 150. Further, the size, luminosity, and/or wavelength(s) of the LEDs 200 may vary from one concentric circle 202 or portion to another. Any combinations of these and additional features of the LEDs 200 may be used in the optical array 150.

The optical array 150 comprises one or more driver circuits (hereinafter the drivers) 206 arranged on the PCB 201. While multiple drivers 206 are shown, a single driver 206 may be used. The following description of the drivers 206 applies to the single driver when used. The drivers 206 control the LEDs 200 as described below in detail. For example, the drivers 206 may be arranged on the PCB 201 on the same side as the LEDs 200, on the opposite side of the PCB 201, or on both sides of the PCB 201. For example, one or more of the drivers 206 may be arranged along different radii on the PCB 201. For example, the drivers 206 may be arranged in a regular pattern or in an irregular pattern (e.g., randomly) on the PCB 201. Furthermore, FIGS. 2A, 4A, 5A, 6A, 8A, and 9A are only representative. In use, the optical array 150 in all these figures is fully populated from the inner annular region 204 of the optical array 150 up to the OD of the optical array 150 across the pedestal. Specifically, regions of the optical array 150 over the drivers 206 are also populated with the LEDs 200.

In FIG. 2B, the optical array 150 comprises a transparent window (hereinafter the window) 210. For example, the window 210 may be made of an optically transparent, chemically resistant, and electrically insulating material such as quartz or sapphire. The window 210 comprises an opening in the center region that coincides with the inner annular region 204 of the optical array 150. The opening has a diameter that matches the diameter of the inner annular region 204 of the optical array 150. The inner annular region 204 is provided so that a shaft (described below) can pass through the inner annular region 204 to move and rotate the substrate 140 (e.g., to raise the substrate 140 above the window 210 to purge the window 210 as described below). In implementations where the shaft is not used, providing the inner annular region 204 and the corresponding opening are unnecessary, and the LEDs 200 can be provided all the way to the center of the optical array 150. The inner and outer peripheries of the window 210 are sealingly attached to the inner and outer peripheries of the optical array 150, respectively. Accordingly, the optical array 150 and the window 210 form a sealed enclosure in which the LEDs 200 and the PCB 201 are housed. Further, portions of the inside (e.g., base and sides) of the sealed enclosure can be shaped and/or equipped with reflective material (e.g., reflective rings) to reflect and/or direct the light emitted by the LEDs 200 onto the substrate 140.

In FIG. 2C, each driver 206 may control a set (group) of LEDs 200. The controller 190 may control the LEDs 200 by controlling the drivers 206. For example, as described below with reference to FIG. 13, after the substrate 140 is loaded into the processing chamber 101, the drivers 206 may supply power to the LEDs 200 at a first power level to preheat the substrate 140 while the substrate 140 is held above the pedestal 130 before the substrate 140 is lowered onto the pedestal 130 for depositing a film on the substrate 140. Subsequently, after a predetermined amount of time for which the substrate 140 is preheated, the drivers 206 may supply a reduced amount of power to the LEDs 200 at a second power level to heat the substrate 140 before or after the substrate 140 is lowered onto the pedestal 130. Subsequently, after the film is deposited on the substrate 140, the drivers 206 may supply a reduced amount of power to the LEDs 200 at a third power level before the substrate 140 is lifted off the pedestal 130 and removed from the processing chamber 101.

Additionally, in any of the steps described above, the drivers 206 may further control the power supplied to the LEDs 200. For example, each driver 206 may control a duty cycle (on/off times) of the respective LEDs 200. For example, each driver 206 may control the intensity (brightness) of the respective LEDs 200. For example, the controller 190 may control the drivers 206 such that only LEDs in selected concentric circles 202 or portions thereof are turned on or off at different times. For example, the controller 190 may control the drivers 206 such that only one or more LEDs 200 in a set (e.g., a zone or portion of the optical array 150) are turned on or off at different times. For example, the controller 190 may control the drivers 206 such that the LEDs 200 or different portions of the LEDs 200 can output varying amounts of light (i.e., optical heating power) at different times. The drivers 206 may control the power supplied to the LEDs 200 gradually or in steps. Any combination of these and additional controls may be used to control the LEDs 200.

In some examples, a portion or the entirety of the control provided by the controller 190 may be offloaded (in the form of hardware, firmware, or a combination thereof) into one or more drivers 206. In some examples, one or more drivers 206 may control the remaining drivers 206. In addition, the substrate 140 can be rotated relative to the optical array 150 as described below. The controller 190 and/or the drivers 206 can control the LEDs 200 differently before and after the substrate 140 is rotated. Thus, optical heating of different portions of the substrate 140 can be controlled by controlling one or more LED 200.

### Section 3: Vaccum Clamping

FIGS. 3A and 3B show an example of the optical array 150 implemented in the pedestal 130 when vacuum clamping is used to clamp the substrate 140 to the pedestal 130. In addition, along with vacuum clamping, these figures show the purging and rotation schemes used to maintain the window 210 clean and to rotate the substrate 140 relative to the optical array 150. FIG. 3A shows an example of vacuum clamping. FIG. 3B shows the purging of the window 210 when the substrate 140 is lifted from the pedestal 130 and is rotated.

In FIG. 3A, the optical array 150 along with the window 210 is disposed in an annular cavity 138 formed in the base portion 132 of the pedestal 130. The annular cavity 138 is formed by removing material from the top surface of the base portion 132 of the pedestal 130 except from a center region of the top surface of the base portion 132 of the pedestal 130. A depth of the annular cavity 138 is equal to a height of the optical array 150 and the window 210. The optical array 150 and the base portion 132 of the pedestal 130 are coplanar. Accordingly, a top surface of the window 210 is level with a top edge 139 of the base portion 132 of the pedestal 130. The substrate 140 is arranged on the top surface of the window 210 during processing. Vacuum clamping described below is used to clamp the substrate 140 to the pedestal 130.

The stem portion 134 of the pedestal 130 comprises a shaft 250. The shaft 250 extends through the centers of the stem portion 134 and the base portion 132 of the pedestal 130. The shaft 250 comprises a T-shaped end (i.e., the horizontal portion that forms the top of the T shape) and a distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. A top surface of the T-shaped end of the shaft 250 is level with top surface of the window 210. A bottom surface of the T-shaped end of the shaft 250 is level with and rests on top of the center region of the top surface of the base portion 132 of the pedestal 130. A diameter of the T-shaped end of the shaft 250 is slightly less than the diameter of the inner annular region 204 of the optical array 150 and the opening of the window 210.

The distal end of the shaft 250 extends through the bottom end of the stem portion 134 of the pedestal 130. The distal end of the shaft 250 extends through the vacuum pump 180 attached to the bottom end of the stem portion 134 of the pedestal 130. One of the actuators 170 is attached to the distal end of the shaft 250. The actuator 170 can move the shaft 250 through the vacuum pump 180 and through the stem portion 134 and the base portion 132 of the pedestal 130 to lift and lower the substrate 140. In FIG. 3B, when lifted, the substrate 140 is held by the T-shaped end of the shaft 250. When lifted, the actuator 170 can also rotate the shaft 250 to rotate the substrate 140 relative to the optical array 150.

A conduit 252 is bored through the shaft 250. The conduit 252 and the shaft 250 are coaxial. The conduit 252 extends through the shaft 250 up to the T-shaped end of the shaft 250. The shaft 250 comprises a plurality of holes 254 bored radially through the T-shaped end of the shaft 250. Near the T-shaped end of the shaft 250, one end of the conduit 252 connects to the plurality of holes 254. A distal end of the conduit 252 extends out of the distal end of the shaft 250. The distal end of the conduit 252 is connected to one of the gas sources 104 through the valve 152 (shown in FIG. 1). In FIG. 3B, when the shaft 250 lifts the substrate 140, a purge gas is supplied through the conduit 252. The purge gas flows through the conduit 252, flows out through the holes 254, and flows radially across and over the window 210 in the direction of the arrows shown to clean the window 210.

The stem portion 134 of the pedestal 130 further comprises a conduit 256 through which electrical connections (e.g., insulated wires or conductors) to the electrical elements in the base portion 132 of the pedestal 130 are routed. The distal ends of the electrical connections are connected to the controller 190 (shown in FIG. 1). The conduit 256 is bored through and extends through the stem portion 134 of the pedestal 130. The conduit 256 extends into the base portion 132 of the pedestal 130 up to the inner annular region 204 of the optical array 150. The conduits 252, 256 and the shaft 250 are coaxial. A diameter of the conduit 256 is greater than the diameter of the shaft 250.

The stem portion 134 of the pedestal 130 further comprises a conduit 258. A diameter of the conduit 258 is greater than the diameter of the conduit 256 and less than the diameter of the stem portion 134 of the pedestal 130. The conduits 258, 252, 256 and the shaft 250 are coaxial. A first end of the conduit 258 is in fluid communication with the vacuum pump 180. A second end of the conduit 258 extends through the stem portion 134 of the pedestal 130 and into the base portion 132 of the pedestal 130. The second end of the conduit 258 extends into the base portion 132 of the pedestal 130 up to a point below the optical array 150. At the second end, the conduit 258 connects to a first set of conduits (or passages) 260 bored radially through the base portion 132 of the pedestal 130 below the optical array 150. The conduits 260 extend up to the OD of the base portion 132 of the pedestal 130. The conduits 260 are in fluid communication with the conduit 258.

A second set of conduits 262 is bored perpendicularly to the first set of conduits 260 through the base portion 132 of the pedestal 130. The conduits 262 extend from the conduits 260 through the optical array 150 and the window 210. The conduits 262 are in fluid communication with the conduits 260, 258. Accordingly, when the substrate 140 is to be clamped to the pedestal 130, the controller 190 activates the vacuum pump 180 and opens the valve 184 (shown in FIG. 1) to create vacuum in the conduits 258, 260, 262. The vacuum in the conduits 258, 260, 262 clamps the substrate 140 to the pedestal 130. After the substrate is clamped to the pedestal 130, the controller 190 controls the optical array 150 to heat the substrate 140 as described above according to the process to be performed on the substrate 140.

In FIG. 3B, when the substrate 140 needs to be rotated relative to the optical array 150, the controller 190 controls the vacuum pump 180 and the valve 184 such that the vacuum in the conduits 258, 260, 262 is reduced. The vacuum in the conduits 258, 260, 262 is sufficiently reduced to allow the shaft 250 to lift the substrate 140. The controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140.

When the substrate 140 is lifted, the controller 190 opens the valve 152 (shown in FIG. 1) to allow the purge gas to flow through the conduit 252 and through the holes 254. The purge gas flows through the conduit 252 and the holes 254 radially over and across the window 210 as shown by arrows in FIG. 3B. The flow of the purge gas over and across the window 210 removes any material that may be deposited on the window 210. The controller 190 controls the valves 152 and 184 (shown in FIG. 1) such that the vacuum pump 180 continues suction though the conduits 258, 260, 262 and through the processing chamber 101 (shown in FIG. 1). Accordingly, the material removed from the window 210 is evacuated from the processing chamber 101.

Subsequently, the actuator 170 lowers the shaft 250 to place the substrate 140 again on the pedestal 130. The substrate 140 is then vacuum clamped as described above. The optical array 150 again heats the substrate 140 as described above. The procedure is repeated as needed until the processing of the substrate 140 is complete.

Section 4: Array with Mesas to Support Substrate

FIGS. 4A-4E show an example of the optical array 150 implemented in the pedestal 130 with a top surface of the window 210 comprising mesas to support the substrate 140 during processing. No other clamping method is used to clamp the substrate 140 to the pedestal 130. In addition, these figures show the purging and rotation schemes used to maintain the window 210 clean and to rotate the substrate 140 relative to the optical array 150.

FIGS. 4A and 4B show an example of the optical array 150 with the window 210 comprising the mesas. FIG. 4A shows a top view of the optical array 150 with the mesas arranged on the top surface of the window 210. FIG. 4B shows a cross-sectional view of the optical array 150 taken along line A-A shown in FIG. 4A. FIG. 4C shows a first example of the pedestal 130 with the optical array 150 comprising the mesas. FIG. 4D shows a first method of purging of the window 210 when the substrate 140 is lifted from the pedestal 130 and is rotated. FIG. 4E shows a second example of the pedestal 130 with the optical array 150 comprising the mesas. FIG. 4F shows a second method of purging of the window 210 when the substrate 140 is lifted from the pedestal 130 and is rotated.

FIGS. 4A and 4B are similar to FIGS. 2A and 2B except that the top surface of the window 210 additionally comprises mesas 214. Therefore, all other description of FIGS. 2A-2C applies to FIGS. 4A-4E and is not repeated for brevity. The mesas 214 are tiny bumps or small generally cylindrical elements that are raised above the top surface of the window 210. The mesas 214 are formed integrally (i.e., homogenously) on the top surface of the window 210. Therefore, the mesas 214 comprise the same optically transparent, chemically resistant, and electrically insulating material such as quartz or sapphire as the window 210. The mesas 214 can be distributed anywhere on the top surface of the window 210 between the LEDs 200 and projecting towards the substrate 140. The number, size, and shapes of the mesas 214 can vary. The mesas 214 can be circular, square, hexagonal, or any other polygonal shape (or any combination thereof). While only a few mesas 214 are shown for illustrative purposes, it is understood that the mesas 214 are distributed throughout the top surface of the window 210 similar to the extent to which the LEDs 200 are distributed throughout the optical array 150.

The mesas 214 are patterned on the top surface of the window 210 such that the mesas 214 are interstitial with the LEDs 200. For example, the mesas 214 can be arranged on the window 210 in concentric circles that coincide with the concentric circles 202 in which the LEDs 200 are arranged. For example, in each concentric circle on the window 210, the mesas 214 can be arranged such that each mesa 214 lies between two adjacent LEDs 200 arranged in the corresponding concentric circle 202.

Additionally, the mesas 214 can be arranged in additional concentric circles 203 on the window 210 such that each additional circle 203 comprising the mesas 214 lies between two consecutive concentric circles 202 in which the LEDs 200 are arranged. On the window 210, the concentric circles 203 comprising the mesas 214 and the concentric circles that coincide with the concentric circles 202 and that comprise the mesas 214 can extend from the opening at the center of the window 210 to an OD of the window 210 in an alternating manner. In some examples, a plurality of concentric circles 203 comprising the mesas 214 may be arranged between two consecutive concentric circles that coincide with the concentric circles 202 and that comprise the mesas 214. The mesas 214 can be arranged on the window 210 using various other arrangements. When the substrate 140 is arranged on the mesas 214, the controller 190 controls the optical array 150 to heat the substrate 140 as described above.

FIGS. 4C and 4D show a first method of purging the window 210. In the first method, the purge gas flows from the holes 254 in the shaft 250 radially outwards over the mesas 214 on the window 210 as described below. In FIG. 4C, the optical array 150 along with the window 210 comprising the mesas 214 is disposed in the annular cavity 138 formed in the base portion 132 of the pedestal 130 as described above. The depth of the annular cavity 138 is equal to the height of the optical array 150 and the window 210 minus the height of the mesas 214. The optical array 150 and the base portion 132 of the pedestal 130 are coplanar. Accordingly, the top surface of the window 210 lies in a plane in which the bases of the mesas 214 and the top edge 139 of the base portion 132 of the pedestal 130 lie. The top ends of the mesas 214 extend above the plane in which the top surface of the window 210 and the top edge 139 of the base portion 132 of the pedestal 130 lie. The top ends of the mesas 214 support the substrate 140 during the processing.

The stem portion 134 of the pedestal 130 comprises the shaft 250. The shaft 250 extends through the centers of the stem portion 134 and the base portion 132 of the pedestal 130. The shaft 250 comprises the T-shaped end (i.e., the horizontal portion that forms the top of the T shape) and the distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. The top surface of the T-shaped end of the shaft 250 is level with top surface of the window 210. The bottom surface of the T-shaped end of the shaft 250 is level with and rests on top of the center region of the top surface of the base portion 132 of the pedestal 130. The diameter of the T-shaped end of the shaft 250 is slightly less than the diameter of the inner annular region 204 of the optical array 150 and the opening of the window 210

The distal end of the shaft 250 extends through the bottom end of the stem portion 134 of the pedestal 130. One of the actuators 170 is attached to the distal end of the shaft 250. The actuator 170 can move the shaft 250 through the stem portion 134 and the base portion 132 of the pedestal 130 to lift and lower the substrate 140. In FIG. 4D, when lifted, the substrate 140 is held by the T-shaped end of the shaft 250. When lifted, the actuator 170 can also rotate the shaft 250 to rotate the substrate 140 relative to the optical array 150.

The conduit 252 is bored through the shaft 250. The conduit 252 and the shaft 250 are coaxial. The conduit 252 extends through the shaft 250 up to the T-shaped end of the shaft 250. The shaft 250 comprises the plurality of holes 254 bored radially through the T-shaped end of the shaft 250. Near the T-shaped end of the shaft 250, one end of the conduit 252 connects to the plurality of holes 254. The distal end of the conduit 252 extends out of the distal end of the shaft 250. The distal end of the conduit 252 is connected to one of the gas sources 104 through the valve 152 (shown in FIG. 1). In FIG. 4D, when the shaft 250 lifts the substrate 140, the purge gas is supplied through the conduit 252. The purge gas flows through the conduit 252, flows out through the holes 254, and flows radially across and over the window 210 in the direction of the arrows shown to clean the window 210 and the mesas 214.

In some examples, the shaft 250 can extend above the window 210 such that a top surface of the T-shaped end of the shaft 250 is level with the with the top ends of the mesas 214. Accordingly, the substrate 140 rests on the mesas 214 and on the top surface of the T-shaped end of the shaft 250. The holes 254 can be located in the T-shaped end of the shaft 250 such that the holes 254 are above the top surface of the window 210 (i.e., above the bases of the mesas 214) but below the top surface of the T-shaped end of the shaft 250 (i.e., below the tops of the mesas 214). Accordingly, the purge gas can be supplied through the conduit 252 and the holes 254 while the substrate 140 rests on the top surface of the T-shaped end of the shaft 250 and the mesas 214. The purge gas can flow through the conduit 252, flow out through the holes 254, and flow radially across and over the window 210 and the mesas 214 to clean the window 210 and the mesas 214 while the substrate 140 is being processed.

The stem portion 134 of the pedestal 130 further comprises the conduit 256 through which electrical connections (e.g., insulated wires or conductors) to the electrical elements in the base portion 132 of the pedestal 130 are routed. The distal ends of the electrical connections are connected to the controller 190 (shown in FIG. 1). The conduit 256 is bored through and extends through the stem portion 134 of the pedestal 130. The conduit 256 extends into the base portion 132 of the pedestal 130 up to the inner annular region 204 of the optical array 150. The conduits 252, 256 and the shaft 250 are coaxial. The diameter of the conduit 256 is greater than the diameter of the shaft 250.

In FIG. 4D, when the substrate 140 needs to be rotated relative to the optical array 150, the controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140.

When the substrate 140 is lifted, the controller 190 opens the valve 152 (shown in FIG. 1) to allow the purge gas to flow through the conduit 252 and through the holes 254. The purge gas flows through the conduit 252 and the holes 254 radially over and across the window 210 and the mesas 214 as shown by arrows in FIG. 4D. The flow of the purge gas radially over and across the window 210 and the mesas 214 removes any material that may be deposited on the window 210 and the mesas 214. The controller 190 controls the valves 152 and 184 (shown in FIG. 1) such that the vacuum pump 180 the material removed from the window 210 and the mesas 214 is evacuated from the processing chamber 101.

Subsequently, the actuator 170 lowers the shaft 250 to place the substrate 140 again on the mesas 214. The optical array 150 again heats the substrate 140 as described above. The procedure is repeated as needed until the processing of the substrate 140 is complete.

FIGS. 4E and 4F show a second method of purging the window 210. In the second method, the purge gas is supplied through holes 141 in top edge 139 of the base portion 132 of the pedestal 130. The purge gas flows from the holes 141 radially inwards over the mesas 214 on the window 210 as described below.

In FIG. 4E, the optical array 150 along with the window 210 comprising the mesas 214 is disposed in the annular cavity 138 formed in the base portion 132 of the pedestal 130 as described above. The depth of the annular cavity 138 is greater than the height of the optical array 150 and the window 210 plus the height of the mesas 214. The optical array 150 and the base portion 132 of the pedestal 130 are coplanar. Accordingly, the top surface of the window 210 and the top ends of the mesas 214 lie below a plane in which the top edge 139 of the base portion 132 of the pedestal 130 lies. A diameter of substrate 140 is less than an inner diameter (ID) of the annular cavity 138. Accordingly, the substrate 140 rests on the top ends of the mesas 214 and is surrounded by the top edge 139 of the base portion 132 of the pedestal 130.

The stem portion 134 of the pedestal 130 comprises the shaft 250. The shaft 250 extends through the centers of the stem portion 134 and the base portion 132 of the pedestal 130. The shaft 250 comprises the T-shaped end (i.e., the horizontal portion that forms the top of the T shape) and the distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. The top surface of the T-shaped end of the shaft 250 is level with top surface of the window 210. The bottom surface of the T-shaped end of the shaft 250 is level with and rests on top of the center region of the top surface of the base portion 132 of the pedestal 130. The diameter of the T-shaped end of the shaft 250 is slightly less than the diameter of the inner annular region 204 of the optical array 150 and the opening of the window 210.

The distal end of the shaft 250 extends through the bottom end of the stem portion 134 of the pedestal 130. One of the actuators 170 is attached to the distal end of the shaft 250. The actuator 170 can move the shaft 250 through the stem portion 134 and the base portion 132 of the pedestal 130 to lift and lower the substrate 140. In FIG. 4F, when lifted, the substrate 140 is held by the T-shaped end of the shaft 250. When lifted, the actuator 170 can also rotate the shaft 250 to rotate the substrate 140 relative to the optical array 150.

The stem portion 134 of the pedestal 130 comprises the conduit 256 through which electrical connections (e.g., insulated wires or conductors) to the electrical elements in the base portion 132 of the pedestal 130 are routed. The distal ends of the electrical connections are connected to the controller 190 (shown in FIG. 1). The conduit 256 is bored through and extends through the stem portion 134 of the pedestal 130. The conduit 256 extends into the base portion 132 of the pedestal 130 up to the inner annular region 204 of the optical array 150. The conduit 256 and the shaft 250 are coaxial. The diameter of the conduit 256 is greater than the diameter of the shaft 250.

The pedestal 130 further comprises the conduit 252 that is bored through and that extends through the stem portion 134 of the pedestal 130. A diameter of the conduit 252 is greater than the diameter of the conduit 256 and less than the diameter of the stem portion 134 of the pedestal 130. The conduit 252 surrounds the conduit 256. The conduits 252, 256 and the shaft 250 are coaxial.

A first end of the conduit 252 is connected to one of the gas sources 104 through the valve 152 shown in FIG. 1. A second end of the conduit 252 extends through the stem portion 134 of the pedestal 130 and into the base portion 132 of the pedestal 130. The second end of the conduit 252 extends into the base portion 132 of the pedestal 130 up to a point below the optical array 150. At the second end, the conduit 252 connects to a first set of conduits (or passages) 261 bored radially through the base portion 132 of the pedestal 130 below the optical array 150. The conduits 261 extend up to the OD of the base portion 132 of the pedestal 130. The conduits 261 are in fluid communication with the conduit 252.

A second set of conduits 263 is bored perpendicularly to the first set of conduits 261 through the periphery (i.e., near the OD) of the base portion 132 of the pedestal 130. The conduits 263 extend from the conduits 261 and surround the optical array 150 and the window 210. The conduits 263 are in fluid communication with the conduits 261, 252. The distal ends of the conduits 263 extend radially inward near the top edge 139 of the base portion 132 of the pedestal 130 and form the holes 141 at the top edge 139 of the base portion 132 of the pedestal 130.

Accordingly, when the substrate 140 rests on the mesas 214 and is being processed, the controller 190 opens the valve 152 (shown in FIG. 1) to supply the purge gas through in the conduits 252, 261, 263. The purge gas in the conduits 252, 261, 263 flows out through the holes 141 in the top edge 139 of the base portion 132 of the pedestal 130. The purge gas from the holes 141 flows radially over and across the mesas 214 on the window 210 to clean the window 210 and the mesas 214. The flow of the purge gas radially over and across the window 210 removes any material that may be deposited on the window 210 and the mesas 214. The controller 190 controls the valves 152 and 184 (shown in FIG. 1) such that the vacuum pump 180 the material removed from the window 210 and the mesas 214 is evacuated from the processing chamber 101.

In FIG. 4F, when the substrate 140 needs to be rotated relative to the optical array 150, the controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140.

When the substrate 140 is lifted, the purge gas is supplied through the conduits 252, 261, 263. The purge gas in the conduits 252, 261, 263 flows out through the holes 141 in the top edge 139 of the base portion 132 of the pedestal 130. The purge gas from the holes 141 flows radially over and across the mesas 214 on the window 210 as shown by arrows in FIG. 4F to clean the window 210 and the mesas 214. The flow of the purge gas radially over and across the window 210 removes any material that may be deposited on the window 210 and the mesas 214. The controller 190 controls the valves 152 and 184 (shown in FIG. 1) such that the vacuum pump 180 the material removed from the window 210 is evacuated from the processing chamber 101.

Subsequently, the actuator 170 lowers the shaft 250 to place the substrate 140 again on the mesas 214. The optical array 150 again heats the substrate 140 as described above. The procedure is repeated as needed until the processing of the substrate 140 is complete.

### Section 5: Electrostatic Clamping

This section is organized as follows. FIGS. 5A-7B show an example of the optical array 150 implemented in the pedestal 130 when electrostatic clamping is used to clamp the substrate 140 to the pedestal 130. FIGS. 5A and 5B show an example of the optical array 150 comprising clamping electrodes made of an electrically conductive material that is also optically transparent. FIG. 5A shows a top view of the optical array 150 comprising clamping electrodes made of an electrically conductive and optically transparent material. FIG. 5B shows a cross-sectional view of the optical array 150 taken along line A-A shown in FIG. 5A. FIGS. 6A and 6B show an example of the optical array 150 comprising clamping electrodes made of a metallic material. FIG. 6A shows a top view of the optical array 150 comprising clamping electrodes made of a metallic material. FIG. 6B shows a cross-sectional view of the optical array 150 taken along line A-A shown in FIG. 6A. FIG. 6C shows a biasing system comprising DC and AC (i.e., RF) power supplies to bias the clamping electrodes shown in FIGS. 5A-6B. FIGS. 7A and 7B show the pedestal 130 comprising the optical array 150, which can comprise the clamping electrodes shown in FIGS. 5A and 5B or the clamping electrodes shown in FIGS. 6A and 6B. In addition, FIGS. 7A and 7B show the purging and rotation schemes used to maintain the window 210 clean and to rotate the substrate 140 relative to the optical array 150. Use of a Faraday shield (also called a Faraday cage) is shown and described with reference to FIGS. 8A-10B.

FIGS. 5A and 5B are similar to FIGS. 2A and 2B except that the optical array 150 shown in FIGS. 5A and 5B further comprises clamping electrodes 300 made of an optically transparent material. Therefore, all other description of FIGS. 2A-2C applies to FIGS. 5A-10B and is not repeated for brevity. For example, the clamping electrodes 300 can be made of an electrically conductive and optically transparent material such as indium tin oxides. The clamping electrodes 300 need to be optically transparent in addition to being electrically conductive as that helps with reflected radiation and the transmission of photons. The material does not significantly reduce the heating efficiency of the optical array 150. In addition, the material does not reflect much of the light radiated from the LEDs 200 back to the PCB 201 and thus does not overheat the LEDs 200. Accordingly, sufficient heat flux can be imparted to the substrate 140 even in high temperature applications. The clamping electrodes 300 need to be located close to the upper surface of the optical array 150 such as embedded within the window 210 as a discrete layer, as shown in FIG. 5B. The optical array 150 needs to be located far below the plane in which the clamping electrodes 300 are embedded in the window 210. The clamping electrodes 303 and the window 210 are coplanar.

The number, size, and shapes of the clamping electrodes 300 can be varied. Electrical connections to the clamping electrodes 300 are provided through the inner annular region 204 of the optical array 150 and the corresponding opening in the window 210. The electrical connections to the clamping electrodes 300 are routed to one or more power supplies (shown in FIG. 6C) through the conduit 256 (shown in FIGS. 7A-7B and 10A-10B). The controller 190 (shown in FIG. 6C) controls the power supplies to bias the clamping electrodes 300 to clamp the substrate 140 to the pedestal 130 as described below.

FIGS. 6A and 6B are similar to FIGS. 2A and 2B except that the optical array 150 shown in FIGS. 6A and 6B further comprises clamping electrodes 302 made of a metallic material. Therefore, all other description of FIGS. 2A-2C applies to FIGS. 6A-10B and is not repeated for brevity. For example, the clamping electrodes 302 can be made of an electrically conductive and optically non-transparent material such as a metal. The clamping electrodes 302 are embedded in the window 210. The clamping electrodes 302 and the window 210 are coplanar. The clamping electrodes 302 comprise a hole pattern that matches the pattern in which the LEDs 200 are arranged on the PCB 201. Accordingly, the light emitted from the LEDs 200 passes through the holes in the clamping electrodes 302 and through the window 210 to the substrate 140 arranged on the window 210. The clamping electrodes 302 need to be located close to the upper surface of the optical array 150 such as embedded within the window 210 as a discrete layer, as shown in FIG. 6B. The optical array 150 needs to be located far below the plane in which the clamping electrodes 300 are embedded in the window 210.

Unlike the clamping electrodes 300, the clamping electrodes 302 may not help with reflected radiation and the transmission of photons. The clamping electrodes 302 may reduce the heating efficiency of the optical array 150. In addition, the clamping electrodes 302 may reflect some of the light radiated from the LEDs 200 back to the PCB 201 and thus heating the LEDs 200. Accordingly, sufficient heat flux may not be imparted to the substrate 140 except in low temperature applications (e.g., patterning ALD oxide, which is processed at about 50 C). To minimize these effect, an anti-reflective coating may be applied to surfaces of the clamping electrodes 302 facing the LEDs 20.

The number, size, and shapes of the clamping electrodes 302 can be varied. Electrical connections to the clamping electrodes 302 are provided through the inner annular region 204 of the optical array 150 and the corresponding opening in the window 210. The electrical connections to the clamping electrodes 302 are routed to one or more power supplies (shown in FIG. 6C) through the conduit 256 (shown in FIGS. 7A and 7B). The controller 190 (shown in FIG. 6C) controls the power supplies to bias the clamping electrodes 302 to clamp the substrate 140 to the pedestal 130 as described below.

FIG. 6C shows a biasing system comprising DC and AC (i.e., RF) power supplies 310, 312 to bias the clamping electrodes 300, 302 when used in the pedestal 130 as shown in FIGS. 7A-7B and 10A-10B. The description of FIG. 6C applies to the FIGS. 5A-6B and 8A-10B. While a single DC power supply 310 and a single AC power supply 312 are shown, multiple DC and AC power supplies may be used instead. Throughout the following description of FIGS. 6C-10B, if electrodes or clamping electrodes are referenced without reference numerals 300 or 302, it is understood that the electrodes or clamping electrodes referenced are either the clamping electrodes 300 or the clamping electrodes 302. In each of the clamping electrodes 300 and 302, the electrodes are electrically insulated from each other. The electrodes are electrically isolated from each other by the dielectric material of the window 210. A small, finite gap exists between the electrodes to provide electrical isolation between them.

In some examples, all of the electrodes may be coplanar and may function as clamping electrodes and are DC biased by the DC power supply 310. For example, the electrodes may be pie-shaped, arcuate, or any other shape. In other examples, the electrodes may be arranged such that all but one electrode constitute inner electrodes that lie in a first plane, and one of the electrodes constitutes an outer electrode that lies in a second plane that is parallel to the first plane. For example, the inner electrodes may be pie-shaped, arcuate, or any other shape; and the outer electrode may be annular and may surround the inner electrodes. For example, the inner electrodes may be pie-shaped, arcuate, or any other shape; and the outer electrode may be in the form of an annular disc. The inner electrodes may have portions that partially overlap the outer electrode. The inner electrodes are DC biased by the DC power supply 310 to clamp the substrate 140 to the pedestal 130, and the outer electrode may be DC or RF biased by the DC and AC power supplies 310, 312 independently of the inner electrodes.

For example, the inner electrodes may be preferentially arranged in a plane parallel to an upper surface of the window 210 (i.e., parallel to the substrate 140). However, the inner electrodes need not be coplanar and may be arranged in one or more planes that are parallel to the upper surface of the window 210. Further, using even number of inner electrodes can simplify DC biasing for electrostatic clamping because the electrodes can be used in pairs. For example, a first pair of electrodes can be connected to a first tap of a bipolar voltage supply (e.g., the DC power supply 310), and a second pair of electrodes can be connected to a second tap of the bipolar voltage supply (e.g., the DC power supply 310).

A switching circuit 314 comprises switches that are controlled by the controller 190 to provide pairing of the electrodes and switching between supplying DC and AC power to the selected electrodes. In some examples, the inner electrodes may be paired differently. For example, the inner electrodes may be paired by pairing adjacent electrodes or by pairing diagonally opposite electrodes. In some examples, the inner electrodes may be connected to a single DC power supply 310 or respective DC power supplies 310. Alternatively, the inner electrodes may be connected to one or more RF power sources (i.e., the AC power supplies 312) instead. The outer electrode may be connected to an RF power source (i.e., the AC power supply 312) or a DC power supply 310. Any combination of DC and AC power may be used to bias any of the electrodes.

Since the biasing system uses both DC and RF biasing, a blocking circuit 316 comprising DC and RF blocking elements such as inductors and capacitors is used. In general, inductors block high frequency from damaging the DC power supplies 310, and capacitors block low frequency like DC from damaging the RF generators (i.e., the AC power supplies 312). For example, the inductors and the capacitors (i.e., the blocking circuit 316) and the switching circuit 314 may be disposed in a facility plate (not shown) of the pedestal 130. In practice, these generalized elements may be implemented as local circuit networks tuned to block a particular frequency to protect the adjacent power source from damage or interference due to the other frequencies present in the system (e.g., the system 100 shown in FIG. 1). The electrical connections between the clamping electrodes and the switching and blocking circuits 314, 316 are routed through the conduit 256 (shown in FIGS. 7A-7B and 10A-10B).

FIGS. 7A and 7B show the pedestal 130 comprising the optical array 150, which can comprise the clamping electrodes 300 shown in FIGS. 5A and 5B or the clamping electrodes 302 shown in FIGS. 6A and 6B. Accordingly, the pedestals 130 shown in FIGS. 7A and 7B can be called electrostatic chucks (ESCs). In addition, FIGS. 7A and 7B show the purging and rotation schemes used to maintain the window 210 clean and to rotate the substrate 140 relative to the optical array 150.

In FIG. 7A, the optical array 150 along with the window 210 comprising the clamping electrodes (300 or 302) is disposed in the annular cavity 138 formed in the base portion 132 of the pedestal 130 as described above. The depth of the annular cavity 138 is equal to the height of the optical array 150 and the window 210. The optical array 150 and the base portion 132 of the pedestal 130 are coplanar. Accordingly, the top surface of the window 210 is level with the top edge 139 of the base portion 132 of the pedestal 130. The substrate 140 is arranged on top surface of the window 210 during the processing. The controller 190 activates the clamping electrodes (300 or 302) to clamp the substrate 140 to the pedestal 130 as described above, and the clamping procedure is therefore not described again for brevity. When the substrate 140 is camped to the pedestal 130, the controller 190 controls the optical array 150 to heat the substrate 140 as described above.

The stem portion 134 of the pedestal 130 comprises the shaft 250. The shaft 250 extends through the centers of the stem portion 134 and the base portion 132 of the pedestal 130. The shaft 250 comprises the T-shaped end (i.e., the horizontal portion that forms the top of the T shape) and the distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. The top surface of the T-shaped end of the shaft 250 is level with top surface of the window 210. The bottom surface of the T-shaped end of the shaft 250 is level with and rests on top of the center region of the top surface of the base portion 132 of the pedestal 130. The diameter of the T-shaped end of the shaft 250 is slightly less than the diameter of the inner annular region 204 of the optical array 150 and the opening of the window 210.

One of the actuators 170 is attached to the distal end of the shaft 250. After the clamping electrodes (300 or 302) are de-clamped by the controller 190, the actuator 170 can move the shaft 250 through the stem portion 134 and the base portion 132 of the pedestal 130 to lift and lower the substrate 140.

The conduit 252 is bored through the shaft 250. The conduit 252 and the shaft 250 are coaxial. The conduit 252 extends through the shaft 250 up to the T-shaped end of the shaft 250. The shaft 250 comprises the plurality of holes 254 bored radially through the T-shaped end of the shaft 250. Near the T-shaped end of the shaft 250, one end of the conduit 252 connects to the plurality of holes 254. The distal end of the conduit 252 extends out of the distal end of the shaft 250. The distal end of the conduit 252 is connected to one of the gas sources 104 through the valve 152 (shown in FIG. 1). In FIG. 7B, when the shaft 250 lifts the substrate 140 after the substrate 140 is de-clamped, the purge gas is supplied through the conduit 252. The purge gas flows through the conduit 252, flows out through the holes 254, and flows radially across and over the window 210 in the direction of the arrows shown to clean the window 210.

The stem portion 134 of the pedestal 130 further comprises the conduit 256 through which electrical connections (e.g., insulated wires or conductors) to the electrical elements in the base portion 132 of the pedestal 130 are routed. The distal ends of the electrical connections are connected to the controller 190 (shown in FIG. 1). The conduit 256 is bored through and extends through the stem portion 134 of the pedestal 130. The conduit 256 extends into the base portion 132 of the pedestal 130 up to the inner annular region 204 of the optical array 150. The conduits 252, 256 and the shaft 250 are coaxial. The diameter of the conduit 256 is greater than the diameter of the shaft 250.

In FIG. 7B, to lift the substrate, the controller 190 deactivates the clamping electrodes (300 or 302). When lifted, the substrate 140 is held by the T-shaped end of the shaft 250. When lifted, the actuator 170 can also rotate the shaft 250 to rotate the substrate 140 relative to the optical array 150. When the substrate 140 needs to be rotated relative to the optical array 150, the controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140.

When the substrate 140 is lifted, the controller 190 opens the valve 152 (shown in FIG. 1) to allow the purge gas to flow through the conduit 252 and through the holes 254. The purge gas flows through the conduit 252 and the holes 254 radially over and across the window 210 as shown by arrows in FIG. 7B. The flow of the purge gas radially over and across the window 210 removes any material that may be deposited on the window 210. The flow of the purge gas can also prevent any material from flowing to and depositing onto the window 210. Further, the flow of the purge gas can also clean or remove any unwanted contamination that may form on the window 210. The controller 190 controls the valves 152 and 184 (shown in FIG. 1) such that the vacuum pump 180 the material removed from the window 210 is evacuated from the processing chamber 101.

Subsequently, the controller 190 activates the actuator 170 to lower the shaft 250 to place the substrate 140 on the window 210. The controller 190 activates the clamping electrodes (300 or 302) to clamp the substrate 140 to the pedestal 30. The optical array 150 again heats the substrate 140 as described above. The procedure is repeated as needed until the processing of the substrate 140 is complete.

### Section 6: Faraday Shield

This section is organized as follows. FIGS. 8A-10B show an example of the optical array 150 comprising the clamping electrodes (300 or 302) and additionally comprising a Faraday shield 350 implemented in the pedestal 130 when electrostatic clamping is used to clamp the substrate 140 to the pedestal 130. FIGS. 8A and 8B show an example of the optical array 150 comprising clamping electrodes and the Faraday shield 350, both made of an electrically conductive material that is also optically transparent. FIG. 8A shows a top view of the optical array 150 comprising clamping electrodes and the Faraday shield 350, both made of an electrically conductive and optically transparent material. FIG. 8B shows a cross-sectional view of the optical array 150 taken along line A-A shown in FIG. 8A. FIGS. 9A and 9B show an example of the optical array 150 comprising clamping electrodes made of a metallic material and the Faraday shield 350 made of an electrically conductive and optically transparent material. FIG. 9A shows a top view of the optical array 150 comprising clamping electrodes made of a metallic material and the Faraday shield 350 made of an electrically conductive and optically transparent material. FIG. 9B shows a cross-sectional view of the optical array 150 taken along line A-A shown in FIG. 9A. FIGS. 10A and 10B show the pedestal 130 comprising the optical array 150, which comprises the Faraday shield 350 made of an electrically conductive and optically transparent material, and which can comprise the clamping electrodes shown in FIGS. 8A and 8B or the clamping electrodes shown in FIGS. 9A and 9B. In addition, FIGS. 10A and 10B show the purging and rotation schemes used to maintain the window 210 clean and to rotate the substrate 140 relative to the optical array 150.

FIGS. 8A and 8B are similar to FIGS. 5A and 5B except that the optical array 150 shown in FIGS. 8A and 8B further comprises the Faraday shield 350. Therefore, all other description of FIGS. 5A and 5B applies to FIGS. 8A-10B and is not repeated for brevity. In FIGS. 8A and 8B, similar to the clamping electrodes 300, the Faraday shield 350 is also made of the same optically transparent and electrically conductive material as the clamping electrodes 300 (e.g., indium tin oxides). The Faraday shield 350 prevents interference from the LEDs 200 with the RF system 142 used to generate plasma in the processing chamber 101. To prevent the interference, the Faraday shield 350 is located below the clamping electrodes 300 and above the LEDs 200. The Faraday shield 350 is embedded in the window 210 as a discrete layer below the clamping electrodes 300. The dielectric material of the window 210 electrically insulates the Faraday shield 350 and provides electrical isolation between the clamping electrodes 300 and the Faraday shield 350. In some examples, while not shown, the Faraday shield 350 may be disposed below the window 210 and above the LEDs 200. The window 210, the clamping electrodes 300, the Faraday shield 350, and the LEDs 200 lie in respective parallel planes that are parallel to the base portion 132 of the pedestal 130. When implemented in the pedestal 130 as shown in FIGS. 10A and 10B, the Faraday shield 350 can be grounded.

FIGS. 9A and 9B are similar to FIGS. 6A and 6B except that the optical array 150 shown in FIGS. 9A and 9B further comprises the Faraday shield 350. Therefore, all other description of FIGS. 6A and 6B applies to FIGS. 9A-10B and is not repeated for brevity. In FIGS. 9A and 9B, while the clamping electrodes 352 are made of an electrically conductive and optically non-transparent material such as a metal, the Faraday shield 350 is made of the optically transparent and electrically conductive material (e.g., indium tin oxides). The Faraday shield 350 prevents interference from the LEDs 200 with the RF system 142 used to generate plasma in the processing chamber 101. To prevent the interference, the Faraday shield 350 is located below the clamping electrodes 302 and above the LEDs 200. The Faraday shield 350 is embedded in the window 210 as a discrete layer below the clamping electrodes 302. The dielectric material of the window 210 electrically insulates the Faraday shield 350 and provides electrical isolation between the clamping electrodes 302 and the Faraday shield 350. In some examples, while not shown, the Faraday shield 350 may be disposed below the window 210 and above the LEDs 200. The window 210, the clamping electrodes 302, the Faraday shield 350, and the LEDs 200 lie in respective parallel planes that are parallel to the base portion 132 of the pedestal 130. When implemented in the pedestal 130 as shown in FIGS. 10A and 10B, the Faraday shield 350 can be grounded.

FIGS. 10A and 10B show the pedestal 130 comprising the optical array 150, which can comprise the clamping electrodes 300 and the Faraday shield 350 shown in FIGS. 8A and 8B or the clamping electrodes 302 and the Faraday shield 350 shown in FIGS. 9A and 9B. Accordingly, the pedestals 130 shown in FIGS. 10A and 10B can be called electrostatic chucks (ESCs). In addition, FIGS. 10A and 10B show the purging and rotation schemes used to maintain the window 210 clean and to rotate the substrate 140 relative to the optical array 150. FIGS. 10A and 10B are similar to FIGS. 7A and 7B except for the addition of the Faraday shield 350. Therefore, the description of FIGS. 7A and 7B applies to FIGS. 10A and 10B and is not repeated for brevity. In FIGS. 10A and 10B, additional electrical connections to ground the Faraday shield 350 are provided through the conduit 256.

### Section 7: Mechanical Clamping

This section is organized as follows. FIGS. 11A-12C show an example of the optical array 150 implemented in the pedestal 130 when mechanical clamping is used to clamp the substrate 140 to the pedestal 130. FIGS. 11A-11C show the pedestal 130 comprising the optical array 150 and clamping pins 400 mounted on the top edge 139 of the base portion 132 of the pedestal 130. In FIGS. 11A-11C, the window 210 is contained within the top edge 139 of the base portion 132 of the pedestal 130. In addition, FIGS. 11A-11C show the purging and rotation schemes used to maintain the window 210 clean and to rotate the substrate 140 relative to the optical array 150. FIGS. 12A-12C show the pedestal 130 comprising the optical array 150 and clamping pins 400 mounted on the window 210 that extends over and covers the top edge 139 of the base portion 132 of the pedestal 130. In addition, FIGS. 12A-12C show the purging and rotation schemes used to maintain the window 210 clean and to rotate the substrate 140 relative to the optical array 150. While an example of mechanical clamping is shown in FIGS. 11A-12C, other types of mechanical clamping may be used to clamp the substrate 140 instead.

11A-11C show the pedestal 130 comprising the optical array 150 and clamping pins 400 mounted on the top edge 139 of the base portion 132 of the pedestal 130. In FIG. 11A, the optical array 150 along with the window 210 is disposed in the annular cavity 138 formed in the base portion 132 of the pedestal 130 as described above. The depth of the annular cavity 138 is equal to the height of the optical array 150 minus the height of the window 210. The optical array 150 and the base portion 132 of the pedestal 130 are coplanar. Accordingly, the top surface of the window 210 lies in a plane in which the top edge 139 of the base portion 132 of the pedestal 130 lies.

A plurality of clamping pins 400 are arranged on the top edge 139 of the base portion 132 of the pedestal 130. The substrate 140 is clamped and unclamped by rotating the clamping pins 400 in opposite directions as follows. A ring 402 with gear-like teeth (not shown) arranged on portions of an OD of the ring 402 is disposed in the base portion 132 of the pedestal 130. The ring 402 is disposed below the optical array 150 in a plane parallel to the optical array.

A plurality of shafts 404 extend vertically from the OD of the ring 402 through the top edge 139 of the base portion 132 of the pedestal 130 and connect to the bases of the clamping pins 400. A first end of each shaft 404 is connected to a base of a corresponding clamping pin 400. A second end of each shaft 404 comprises a gear (not shown) that engages with the teeth in a corresponding portion of the ring 402. The shafts 404 are disposed around the optical array 150.

An actuator 406 is coupled to the ring 402. The controller 190 controls the actuator 406. The actuator 406 can rotate the ring 402 around a vertical axis of the pedestal 130 in a first direction (e.g., clockwise) and a second direction (e.g., counterclockwise), which is opposite to the first direction. When the actuator 406 rotates the ring 402 in the first direction, the shafts 404 and the clamping pins 400 connected to the shaft 404 rotate (spin) in the second direction. Conversely, when the actuator 406 rotates the ring 402 in the second direction, the shafts 404 and the clamping pins 400 connected to the shaft 404 rotate (spin) in the first direction.

When the clamping pins 400 rotate (spin) in one direction (e.g., the first direction), the substrate 140 is held (clamped) in recesses near the tops of the clamping pins 400. Conversely, when the clamping pins 400 rotate (spin) in opposite direction (e.g., the second direction), the substrate 140 is released (unclamped) from the clamping pins 400. The controller 190 controls the actuator 406 and coordinates clamping and unclamping of the substrate 140 while also controlling the movement of the shaft 250 as shown in FIGS. 11B and 11C. When the substrate is clamped using the clamping pins 400, the controller 190 controls the optical array 150 to heat the substrate 140 as described above.

In FIG. 11B, the stem portion 134 of the pedestal 130 comprises the shaft 250. The shaft 250 extends through the centers of the stem portion 134 and the base portion 132 of the pedestal 130. The shaft 250 comprises the T-shaped end (i.e., the horizontal portion that forms the top of the T shape) and the distal end (i.e., the vertical portion that forms the bottom of the T shape). The T-shaped end of the shaft 250 extends through the inner annular region 204 of the optical array 150, the opening of the window 210, and the center region of the top surface of the base portion 132 of the pedestal 130. The top surface of the T-shaped end of the shaft 250 is level with top surface the window 210. The bottom surface of the T-shaped end of the shaft 250 is level with and rests on top of the center region of the top surface of the base portion 132 of the pedestal 130. The diameter of the T-shaped end of the shaft 250 is slightly less than the diameter of the inner annular region 204 of the optical array 150 and the opening of the window 210.

The distal end of the shaft 250 extends through the bottom end of the stem portion 134 of the pedestal 130. One of the actuators 170 is attached to the distal end of the shaft 250. The actuator 170 can move the shaft 250 through the stem portion 134 and the base portion 132 of the pedestal 130 to lift and lower the substrate 140. In FIG. 11B, when lifted, the substrate 140 is held by the T-shaped end of the shaft 250. When lifted, the actuator 170 can also rotate the shaft 250 to rotate the substrate 140 relative to the optical array 150.

The conduit 252 is bored through the shaft 250. The conduit 252 and the shaft 250 are coaxial. The conduit 252 extends through the shaft 250 up to a point below (i.e., not into) the T-shaped end of the shaft 250. Near the point below the T-shaped end of the shaft 250, the shaft 250 comprises a plurality of holes 255 bored radially through the vertical portion of the shaft 250 that forms the bottom of the T shape of the shaft 250. Near the point below the T-shaped end of the shaft 250, one end of the conduit 252 connects to the plurality of holes 255. The distal end of the conduit 252 extends out of the distal end of the shaft 250. The distal end of the conduit 252 is connected to one of the gas sources 104 through the valve 152 (shown in FIG. 1). In FIG. 11C, when the substrate is unclamped and the shaft 250 lifts the substrate 140, the purge gas is supplied through the conduit 252. The purge gas flows through the conduit 252, flows out through the holes 255, and flows radially across and over the window 210 in the direction of the arrows shown to clean the window 210.

In some examples, the conduit 252 can extend further into the T-shaped end of the shaft 250, and the shaft 250 can additionally comprise the plurality of holes 254 (shown in prior figures) bored radially through the T-shaped end of the shaft 250. The shaft 250 can be extended above the window 210 such that the top surface of the T-shaped end of the shaft 250 is above the top surface of the window. Accordingly, the purge gas can be supplied through the conduit 252 and the holes 254 while the substrate 140 rests on the clamping pins 400. The purge gas can flow through the conduit 252, flow out through the holes 254, and flow radially across and over the window 210 to clean the window 210 while the substrate 140 is being processed.

The stem portion 134 of the pedestal 130 further comprises the conduit 256 through which electrical connections (e.g., insulated wires or conductors) to the electrical elements in the base portion 132 of the pedestal 130 are routed. The distal ends of the electrical connections are connected to the controller 190 (shown in FIG. 1). The conduit 256 is bored through and extends through the stem portion 134 of the pedestal 130. The conduit 256 extends into the base portion 132 of the pedestal 130 up to the inner annular region 204 of the optical array 150. The conduits 252, 256 and the shaft 250 are coaxial. The diameter of the conduit 256 is greater than the diameter of the shaft 250.

In FIG. 11C, when the substrate 140 needs to be rotated relative to the optical array 150, the actuator 406 unclamps the substrate 140 and the controller 190 activates the actuator 170 such that the shaft 250 lifts and rotates the substrate 140. In some applications, the substrate 140 can be lifted and held stationary and the pedestal 130 can be rotated so as to rotate the optical array 150 relative to the substrate 140. In some applications, while not shown, the substrate 140, which is clamped with the clamping pins 400, can be rotated by rotating the base portion 132 of the pedestal 130. In this scenario, the optical array 150 is stationary and is held by a center portion of the stationary stem portion 256 of the pedestal 130.

When the substrate 140 is lifted, the controller 190 opens the valve 152 (shown in FIG. 1) to allow the purge gas to flow through the conduit 252 and through the holes 254. The purge gas flows through the conduit 252 and the holes 255 (and additionally through the holes 254 as described above) radially over and across the window 210 as shown by arrows to clean the window. The flow of the purge gas radially over and across the window 210 removes any material that may be deposited on the window 210. The controller 190 controls the valves 152 and 184 (shown in FIG. 1) such that the vacuum pump 180 the material removed from the window 210 is evacuated from the processing chamber 101.

Subsequently, the actuator 170 lowers the shaft 250 to place the substrate 140 again on the clamping pins 400. The controller 190 controls the actuator 406 to clamp the substrate 140 to the clamping pins 400 as described above. The optical array 150 again heats the substrate 140 as described above. The procedure is repeated as needed until the processing of the substrate 140 is complete.

FIGS. 12A-12C show the pedestal 130 comprising the optical array 150 and clamping pins 400 mounted on the window 210 that extends over and covers the top edge 139 of the base portion 132 of the pedestal 130. In addition, FIGS. 12A-12C show the purging and rotation schemes used to maintain the window 210 clean and to rotate the substrate 140 relative to the optical array 150.

The following are the only differences between FIGS. 12-12C and 11A-11C. In FIGS. 12A-12C, the window 210 extends around and covers the top edge 139 of the base portion 132 of the pedestal 130. Accordingly, the clamping pins 400 are arranged on the top surface of the window 210 along an OD of the window 210 instead of on the top edge 139 of the base portion 132 of the pedestal 130. The shafts 404 extend vertically from the OD of the ring 402 through the top edge 139 of the base portion 132 of the pedestal 130 and through the window 210 and connect to the bases of the clamping pins 400. In some examples, depending on the arrangements of the optical array 150 and the clamping pins 400, the shafts 404 may pass through the optical array 150 to connect to the clamping pins 400. All other description of FIGS. 11A-11C applies to FIGS. 12A-12C and is therefore no repeated for brevity.

### Section 8: Method

FIG. 13 shows a method 500 of processing a substrate using any of the optical arrays and pedestals of FIGS. 2A-12C in the system of FIG. 1 according to the present disclosure. At 502, the substrate 140 is loaded into the processing chamber 101 (shown in FIG. 1). The substrate 140 is not yet placed on the pedestal 130 comprising the optical array 150. For example, the substrate 140 may be held above the pedestal 130 and may be supported by lift pins or other lift mechanism (e.g., the shaft 250).

At 504, optionally, while the substrate 140 is held above the pedestal 130, the substrate 140 is preheated by turning on the optical array 150 and supplying power at a first power level to the LEDs 200. For example, the substrate 140 is preheated for a predetermined period of time.

At 506, the substrate 140 is lowered onto the pedestal 130, and the power supplied to the LEDs 200 is reduced to a second power level. Alternatively, the power supplied to the LEDs 200 is reduced to a second power level, and the substrate 140 is lowered onto the pedestal 130.

At 508, optionally, the substrate 140 is clamped to the pedestal 130 using any of the clamping methods described above. For example, the clamping may be optional when the mesas 214 are used to support the substrate 140 instead of using other clamping methods described above.

At 510, other process conditions such as gas and vapor flows through the showerhead 120, wafer-to-showerhead gap, plasma excitation, etc. for depositing a film on the substrate 140 are established. At 512, a film is deposited on the substrate 140 via a continuum method such as PECVD or with a cyclical deposition method such as ALD. At 514, the other process conditions such as gas and vapor flows, wafer-to-showerhead gap, plasma excitation, etc. are turned off or largely disabled.

At 516, the power to the LEDs 200 is reduced to a third power level. At 518, after a predetermined period of time, the substrate 140 is lifted from the pedestal 130. At this point, if needed, the substrate 140 may be rotated, and steps 508-518 may be repeated. At 520, the substrate 140 is removed from the processing chamber 101.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a metal plating chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal configured to deposit material on a substrate, the pedestal comprising:
a stem portion of the pedestal; and
a base portion of the pedestal mounted to the stem portion of the pedestal, the base portion comprising an array of optical elements configured to emit light to optically heat the substrate.

2. The pedestal of claim 1 wherein the optical elements comprise light emitting diodes.

3. The pedestal of claim 1 wherein the optical elements comprise light emitting diodes configured to emit light having wavelengths between 530 nm and 1000 nm.

4. The pedestal of claim 1 wherein the base portion and the array are coplanar.

5. The pedestal of claim 1 wherein the base portion and the array are circular and wherein the optical elements are arranged in concentric circles from an inner diameter to an outer diameter of the array.

6. The pedestal of claim 1 wherein the base portion and the array are circular and wherein an outer diameter of the array is less or equal to an outer diameter of the base portion.

7. The pedestal of claim 1 wherein the base portion and the array are circular and wherein an outer diameter of the array is less or equal to an outer diameter of the substrate.

8. The pedestal of claim 1 wherein the base portion and the array are circular and wherein an outer diameter of the array is at least equal to an outer diameter of the substrate.

9. The pedestal of claim 1 wherein the array is embedded in a cavity formed in an upper region of the base portion and wherein the array further comprises an optically transparent window covering the optical elements.

10. The pedestal of claim 1 wherein the array further comprises an optically transparent window having a first side covering the optical elements and a second side facing the substrate.

11. The pedestal of claim 1 wherein:
the optical elements are arranged on a printed circuit board (PCB);
the array further comprises an optically transparent window sealingly attached to the PCB; and
a reflective material is disposed on inside portions of the optical array to reflect the light from the optical elements to the substrate.

12. The pedestal of claim 1 wherein the array further comprises one or more driver circuits configured to control power supply to the optical elements.

13. The pedestal of claim 1 wherein the array further comprises one or more driver circuits configured to control operation of selected ones of the optical elements.

14. The pedestal of claim 1 wherein the array comprises:
a printed circuit board on which the optical elements are arranged; and
one or more driver circuits to drive the optical elements,
wherein the one or more driver circuits and the optical elements are arranged on the same side of the printed circuit board.

15. The pedestal of claim 1 wherein the array comprises:
a printed circuit board on which the optical elements are arranged; and
one or more driver circuits to drive the optical elements,
wherein the one or more driver circuits and the optical elements are arranged on opposite sides of the printed circuit board.

16. The pedestal of claim 1 wherein the array comprises:
a printed circuit board; and
a plurality of driver circuits to drive the optical elements,
wherein the optical elements and at least one of the driver circuits is arranged on the same side of the printed circuit board and wherein at least one of the driver circuits is arranged on an opposite side of the printed circuit board than the side on which the optical elements are arranged.

17. The pedestal of claim 1 wherein the pedestal further comprises:
a shaft disposed through centers of the stem portion, the base portion, and the array; and
an actuator coupled to the shaft and configured to move the substrate relative to the pedestal.

18. The pedestal of claim 1 wherein the pedestal further comprises:
a shaft disposed through centers of the stem portion, the base portion, and the array; and
an actuator coupled to the shaft and configured to move the substrate perpendicularly relative to a plane in which the base portion lies.

19. The pedestal of claim 1 wherein the pedestal further comprises:
a shaft disposed through centers of the stem portion, the base portion, and the array; and
an actuator coupled to the shaft and configured to rotate the substrate relative to the base portion.

20. The pedestal of claim 1 wherein the array further comprises an optically transparent window covering the optical elements and wherein the pedestal further comprises:
a shaft disposed through centers of the stem portion, the base portion, and the array, wherein the shaft comprises a conduit to receive a gas and a plurality of holes in fluid communication with the conduit near a first end of the shaft proximate to the array; and
an actuator coupled to a second end of the shaft and configured move the substrate perpendicularly relative to a plane in which the base portion lies,
wherein the plurality of holes supply the gas radially over the window when the shaft is raised above the array.

21. The pedestal of claim 1 wherein the array further comprises an optically transparent window having a first side covering the optical elements and a second side facing the substrate and wherein the window comprises a plurality of mesas on the second side.

22. The pedestal of claim 1 wherein the array further comprises an optically transparent window having a first side covering the optical elements and a second side facing the substrate and wherein the window comprises a plurality of mesas arranged on the second side interstitially with an arrangement of the optical elements in the array.

23. The pedestal of claim 1 wherein:
the base portion and the array are circular;
the optical elements are arranged in concentric circles from an inner diameter to an outer diameter of the array;
the array further comprises a circular and optically transparent window having a first side covering the optical elements and a second side facing the substrate; and
the window comprises a plurality of mesas arranged in concentric circles on the second side interstitially relative to the optical elements.

24. The pedestal of claim 23 wherein the pedestal further comprises:
a shaft disposed through centers of the stem portion, the base portion, and the array, wherein the shaft comprises a conduit to receive a gas and a plurality of holes in fluid communication with the conduit near a first end of the shaft proximate to the array; and
an actuator coupled to a second end of the shaft and configured move the substrate perpendicularly relative to a plane in which the base portion lies,
wherein the plurality of holes supply the gas radially over the window and the mesas when the shaft is raised above the array.

25. The pedestal of claim 23 wherein the pedestal further comprises:
a plurality of conduits disposed in the stem and base portions to receive a gas; and
a plurality of holes at a periphery of the base portion, the holes being level with the mesas on the window and in fluid communication with the conduits,
wherein the holes supply the gas radially over the window and the mesas.

26. The pedestal of claim 1 wherein the array further comprises:
an optically transparent window covering the optical elements; and
a plurality of electrodes disposed in the window to electrostatically clamp the substrate to the pedestal.

27. The pedestal of claim 26 wherein the window and the electrodes are coplanar.

28. The pedestal of claim 26 wherein the electrodes comprise an optically transparent and electrically conductive material.

29. The pedestal of claim 26 wherein the electrodes comprise a metallic material and wherein the electrodes comprise holes aligned with the optical elements.

30. The pedestal of claim 26 further comprising a layer of an optically transparent and electrically conductive material disposed between the electrodes and the optical elements.

31. The pedestal of claim 30 wherein the window, the electrodes, the layer, and the optical elements lie in respective parallel planes that are parallel to the base portion of the pedestal.

32. The pedestal of claim 29 further comprising a layer of an optically transparent and electrically conductive material disposed in the window with one side of the layer facing the electrodes and an opposite side of the layer facing the optical elements.

33. The pedestal of claim 32 wherein the window, the electrodes, the layer, and the optical elements lie in respective parallel planes that are parallel to the base portion of the pedestal.

34. The pedestal of claim 1 further comprising:
a plurality of conduits routed through the stem and base portions and the array; and
a vacuum pump configured to clamp the substrate to the pedestal using vacuum clamping.

35. The pedestal of claim 1 further comprising:
a plurality of clamping pins arranged on a periphery of the base portion; and
an actuator coupled to the clamping pins and configured to clamp the substrate.

36. The pedestal of claim 35 further comprising:
a ring disposed in the base portion adjacent to the array and coupled to the actuator; and
a plurality of shafts disposed in the base portion, the shafts coupled to the ring and attached to respective ones of the clamping pins.

37. The pedestal of claim 36 wherein the shafts are arranged around the array.

38. The pedestal of claim 36 wherein the shafts pass through pins the array.

39. The pedestal of claim 36 wherein the actuator is configured to actuate the ring in a first direction to clamp the substrate and in a second direction to de-clamp the substrate.

40. The pedestal of claim 1 wherein the array further comprises an optically transparent window covering the optical elements and extending to a periphery of the base portion, the pedestal further comprising:
a plurality of clamping pins arranged on the window near the periphery of the base portion; and
an actuator coupled to the clamping pins and configured to clamp the substrate.

41. A method of depositing material on a substrate in a processing chamber, the method comprising:
loading the substrate into the processing chamber; and
optically heating the substrate using an array of optical elements embedded in a base portion of a pedestal in the processing chamber.

42. The method of claim 41 further comprising:
holding the substrate above the pedestal; and
preheating the substrate by supplying power to the optical elements at a first power level.

43. The method of claim 42 further comprising, after the preheating:
lowering the substrate onto the pedestal; and
heating the substrate by supplying power to the optical elements at a second power level that is different than the first power level.

44. The method of claim 42 further comprising, after the preheating:
heating the substrate by supplying power to the optical elements at a second power level that is different than the first power level; and
lowering the substrate onto the pedestal.

45. The method of claim 43 further comprising clamping the substrate to the pedestal using electrostatic clamping, vacuum clamping, or mechanical clamping.

46. The method of claim 45 further comprising establishing other conditions for processing the substrate, the other conditions comprising supplying gas and vapor flows through a showerhead, adjusting substrate-to-showerhead gap, and exciting plasma in the processing chamber.

47. The method of claim 46 further comprising depositing the material on the substrate using plasma enhanced chemical vapor deposition or atomic layer deposition.

48. The method of claim 47 further comprising reducing power supplied to the array to a third power level.

49. The method of claim 48 further comprising:
lifting the substrate from the pedestal; and
removing the substrate from the processing chamber.

50. The method of claim 44 further comprising establishing other conditions for processing the substrate, the other conditions comprising supplying gas and vapor flows through a showerhead, adjusting substrate-to-showerhead gap, and exciting plasma in the processing chamber.

51. The method of claim 50 further comprising depositing the material on the substrate using plasma enhanced chemical vapor deposition or atomic layer deposition.

52. The method of claim 51 further comprising reducing power supplied to the array to a third power level.

53. The method of claim 52 further comprising:
lifting the substrate from the pedestal; and
removing the substrate from the processing chamber.

54. The method of claim 41 further comprising clamping the substrate to the pedestal using electrostatic clamping, vacuum clamping, or mechanical clamping.

55. The method of claim 54 further comprising establishing other conditions for processing the substrate, the other conditions comprising supplying gas and vapor flows through a showerhead, adjusting substrate-to-showerhead gap, and exciting plasma in the processing chamber.

56. The method of claim 55 further comprising depositing the material on the substrate using plasma enhanced chemical vapor deposition or atomic layer deposition.

57. The method of claim 56 further comprising reducing power supplied to the array to a third power level.

58. The method of claim 57 further comprising:
lifting the substrate from the pedestal; and
removing the substrate from the processing chamber.

59. The method of claim 41 further comprising:
arranging the substrate on the pedestal; and
heating the substrate by supplying power to the array.

60. The method of claim 59 further comprising establishing other conditions for processing the substrate, the other conditions comprising supplying gas and vapor flows through a showerhead, adjusting substrate-to-showerhead gap, and exciting plasma in the processing chamber.

61. The method of claim 60 further comprising depositing the material on the substrate using plasma enhanced chemical vapor deposition or atomic layer deposition.

62. The method of claim 61 further comprising reducing power supplied to the array.

63. The method of claim 62 further comprising:
lifting the substrate from the pedestal; and
removing the substrate from the processing chamber.
